(19) United States
(12) Patent Application Publication
(10) Pub. No.: US 2016/0334706 A1
(43) Pub. Date: Nov. 17, 2016

(54) RESIST COMPOSITION AND PATTERNING PROCESS

(71) Applicant: Shin-Etsu Chemical Co., Ltd., Tokyo (JP)

(72) Inventor: Masaki Ohashi, Joetsu-shi (JP)

(73) Assignee: Shin-Etsu Chemical Co., Ltd., Tokyo (JP)

(21) Appl. No.: 15/153,060

(22) Filed: May 12, 2016

(30) Foreign Application Priority Data
May 14, 2015 (JP) 2015-098783

(51) Int. Cl. G03F 7/039; G03F 7/32; G03F 7/38; G03F 7/16; G03F 7/20

(52) U.S. Cl. CPC G03F 7/039; G03F 7/168; G03F 7/2004; G03F 7/2053; G03F 7/38; G03F 7/322; G03F 7/2041

(57) ABSTRACT

A resist composition comprising (A) a base resin of specific structure and (B) an ammonium salt is provided. When processed by ArF, EB or EUV lithography, the resist composition exhibits a high sensitivity and high resolution and is improved in LER.

### CROSS-REFERENCE TO RELATED APPLICATION

This non-provisional application claims priority under 35 U.S.C. §119(a) on Patent Application No. 2015-098783 filed in Japan on May 14, 2015, the entire contents of which are hereby incorporated by reference.

### TECHNICAL FIELD

This invention relates to a chemically amplified resist composition comprising a base resin of specific structure and an ammonium salt, and a patterning process using the resist composition.

### BACKGROUND ART

To meet the demand for higher integration density and operating speed of LSIs, the effort to reduce the pattern rule is in rapid progress. The wide-spreading flash memory market and the demand for increased storage capacities drive forward the miniaturization technology. As the advanced miniaturization technology, the double patterning version of ArF lithography is implemented to manufacture devices of 10 nm order on a mass scale.

The ArF lithography started partial use from the fabrication of 130-nm node devices and became the main lithography since 90-nm node devices. Although lithography using F₂ laser (157 nm) was initially thought promising as the next lithography for 45-nm node devices, its development was retarded by several problems. A highlight was suddenly placed on the ArF immersion lithography that introduces a liquid having a higher refractive index than air (e.g., water, ethylene glycol, glycerol) between the projection lens and the wafer, allowing the projection lens to be designed to a numerical aperture (NA) of 1.0 or higher and achieving a higher resolution. The ArF immersion lithography is now implemented on the commercial stage. The immersion lithography requires a resist material which is substantially insoluble in water.

Recently a highlight is put on the negative tone resist adapted for organic solvent development as well as the positive tone resist adapted for alkaline development. It would be desirable if a very fine hole pattern, which is not achievable with the positive tone, is resolvable through negative tone exposure. To this end, a positive resist material featuring a high resolution is subjected to organic solvent development to form a negative pattern. An attempt to double a resolution by combining two developments, alkali development and organic solvent development is under study.

As the ArF resist material for negative tone development with organic solvent, positive ArF resist compositions of the prior art design may be used. Such pattern forming processes are described in Patent Documents 1 to 3.

The lithography of next generation to the ArF lithography is EUV lithography of wavelength 13.5 nm. For mask writing, the EB lithography is used in the art.

With respect to high-energy radiation of very short wavelength such as EB or EUV, hydrocarbons and similar light elements used in resist materials have little absorption. Then polyhydroxystyrene base resist materials are under consideration.

The exposure system for mask manufacturing made a transition from the laser beam exposure system to the EB exposure system to increase the accuracy of line width. Since a further size reduction became possible by increasing the accelerating voltage of the electron gun in the EB exposure system, the accelerating voltage increased from 10 kV to 30 kV and reached 50 kV in the current mainstream system, with a voltage of 100 kV being under investigation.

As the accelerating voltage increases, a lowering of sensitivity of resist film becomes of concern. As the accelerating voltage increases, the influence of forward scattering in a resist film becomes so reduced that the contrast of electron image writing energy is improved to ameliorate resolution and dimensional control whereas electrons can pass straightforward through the resist film so that the resist film becomes less sensitive. Since the mask exposure tool is designed for exposure by direct continuous writing, a lowering of sensitivity of resist film leads to an undesirably reduced throughput. Due to a need for higher sensitivity, chemically amplified resist compositions are studied.

In the EUV lithography, a tradeoff relationship between sensitivity and edge roughness has been pointed out. For example, Non-Patent Document 1 describes that sensitivity is in inverse proportion to edge roughness. It is expected that the edge roughness of a resist film is reduced by increasing the exposure dose to reduce shot noise. Non-Patent Document 2 describes a tradeoff between sensitivity and roughness in the EUV lithography in that a resist material containing a more amount of quencher is effective in reducing roughness, but suffers from a decline of sensitivity at the same time. This suggests a need for a new resist material capable of solving the problem.

As the miniaturization technology is in a progress from the ArF immersion lithography to the EB lithography and further to the EUV lithography, image blurs and LER degradation due to acid diffusion become noticeable. To insure resolution for fine patterns with a size of 45 nm et seq., not only an improvement in dissolution contrast is important as previously reported, but control of acid diffusion is also important as reported in Non-Patent Document 3. Since chemically amplified resist compositions are designed such that sensitivity and contrast are enhanced by acid diffusion, an attempt to minimize acid diffusion by reducing the temperature and/or time of PEB fails, resulting in drastic reductions of sensitivity and contrast. When another attempt is made to gain sensitivity by increasing the temperature and/or time of PEB or by using a high reactivity base resin like acetal protection type, the influence of acid diffusion becomes more detrimental, leading to a lower resolution and a substantial degradation of LER.

To solve such problems, studies have been made on the FAG. For example, Patent Documents 4 and 5 disclose resist compositions comprising a base resin having a PAG anion moiety incorporated therein. Allegedly acid diffusion is substantially suppressed. These compositions, however, are still insufficient in sensitivity. A further improvement is necessary in the EUV lithography that strongly requires a higher sensitivity.

As the PAG of addition type, a PAG capable of generating an acid with a giant molecular weight is proposed for the purpose of restraining acid diffusion. For example, Patent Document 6 discloses a PAG capable of generating a fluorosulfonic acid of steroid structure. A resist composition using such low diffusion type PAG, however, is insufficient in sensitivity. By increasing the amount of the PAG added, the sensitivity may be elevated to the desired level, but at the substantial sacrifice of LER. All things considered, the state-of-the-art fails to get rid of the tradeoff between sensitivity and LER.

### CITATION LIST

Patent Document 1: JP-A 2008-281974
Patent Document 2: JP-A 2008-281975
Patent Document 3: JP 4554665
Patent Document 4: JP-A 2010-116550
Patent Document 5: JP-A 2010-077404
Patent Document 6: JP-A 2006-045311 (U.S. Pat. No. 7,482,108)
Non-Patent Document 1: SPIE Vol. 3331 p 531 (1998)
Non-Patent Document 2: SPIE Vol. 5374 p 74 (2004)
Non-Patent Document 3: SPIE Vol. 6520 65203L-1 (2007)

### SUMMARY OF INVENTION

An object of the present invention is to provide a chemically amplified resist composition which exhibits a high sensitivity, high resolution, and improved LER, when processed by high-energy lithography, especially ArF, EB or EUV lithography; and a patterning process using the resist composition.

The inventor has found that a resist composition comprising a base resin of specific structure and an ammonium salt solves the outstanding problems and is best suited for precise microprocessing.

In one aspect, the invention provides a resist composition comprising (A) a base resin comprising recurring units (A1) and (A2), and (B) an ammonium salt having the general formula (3). The recurring units (A1) have the general formula (1a) or (1b):

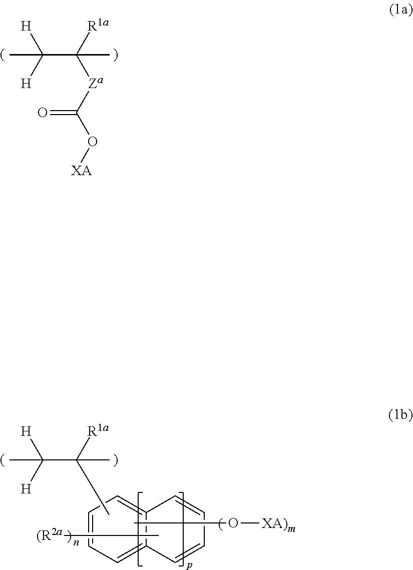

wherein R^{1a} is hydrogen, fluorine, methyl or trifluoromethyl, Z^{a} is a single bond or (backbone)-C(═O)—O—Z′—, Z′ is a straight C₁-C₁₀, branched or cyclic C₃-C₁, alkylene group which may contain a hydroxyl moiety, ether bond, ester bond or lactone ring, or phenylene or naphthylene group, XA is an acid labile group, R^{2a} is a straight C₁-C₁₀, branched or cyclic C₃-C₁₀ monovalent hydrocarbon group which may be substituted with or separated by a heteroatom, m is an integer of 1 to 3, n is an integer satisfying 0≦n≦5+2p−m, and p is 0 or 1. The recurring units (A2) have the general formula (2a) or (2b):

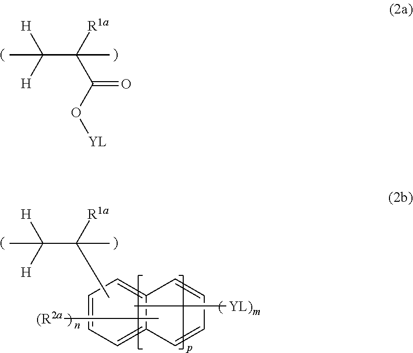

wherein R^{1a}, R^{2a}, m, n and p are as defined above, YL is hydrogen or a polar group having at least one structure selected from the group consisting of hydroxyl, cyano, carbonyl, carboxyl, ether bond, ester bond, sulfonic acid ester bond, carbonate bond, lactone ring, sultone ring, and carboxylic anhydride. The ammonium salt (B) has the general formula (3):

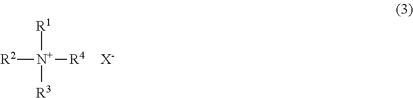

wherein R¹ to R⁴ are each independently a straight C₁-C₂₀, branched or cyclic C₃-C₂₀ monovalent hydrocarbon group which may be substituted with or separated by a heteroatom, any two or more of R¹ to R⁴ may bond together to form a ring with the nitrogen atom to which they are attached, X⁻ is a structure of the general formula (3a), (3b) or (3c):

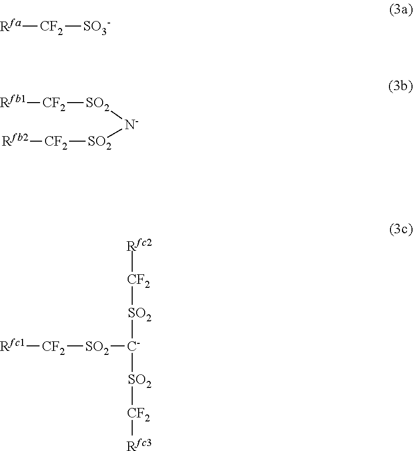

wherein R^{fa}, R^{fb1}, R^{fb2}, R^{fc1}, R^{fc2} and R^{fc3} are each independently fluorine or a straight C₄-C₄₀, branched or cyclic C₃-C₄₀ monovalent hydrocarbon group which may be substituted with or separated by a heteroatom, or a pair of R^{fb1} and R^{fb2}, or R^{fc1} and R^{fc2} may bond together to form a ring with the carbon atom to which they are attached and any intervening atoms.

In a preferred embodiment, the ammonium salt (B) has a structure represented by the general formula (4):

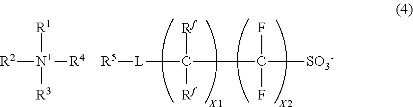

wherein R¹ to R⁴ are as defined above, R⁵ is a straight C₁-C₄₀, branched or cyclic C₃-C₄₀ monovalent hydrocarbon group which may be substituted with or separated by a heteroatom, R^{f1} is each independently hydrogen, fluorine or fluoroalkyl, L is a single bond or linking group, x1 is an integer of 0 to 10, and x2 is an integer of 1 to 5.

In a preferred embodiment, the ammonium salt (B) has a structure represented by the general formula (5):

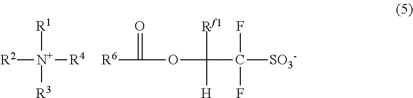

wherein R¹ to R⁴ are as defined above, R⁶ is a straight C₁-C₄₀, branched or cyclic C₃-C₄₀ monovalent hydrocarbon group which may be substituted with or separated by a heteroatom, and RE is each independently hydrogen or trifluoromethyl.

In a preferred embodiment, the base resin (A) further comprises recurring units having the general formula (6a) or (6b):

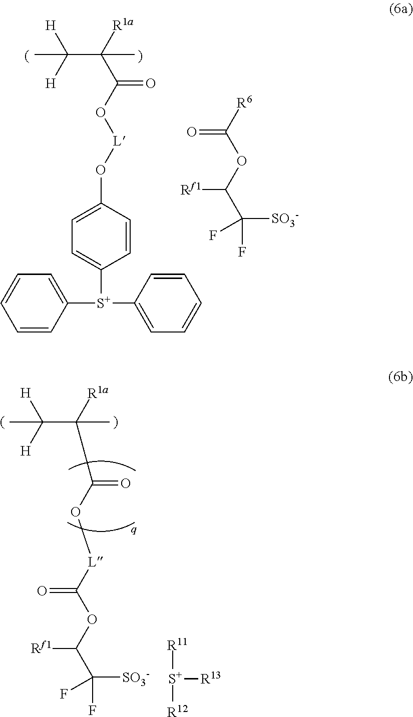

wherein R^{1a}, R⁶ and R^{f1} are as defined above, L′ is C₂-C₅ alkylene, R¹, R¹² and R¹³ are each independently a straight, branched or cyclic C₁-C₁₀ alkyl or alkenyl group which may be substituted with or separated by a heteroatom, or a C₆-C₁₈ aryl group which may be substituted with or separated by a heteroatom, or any two of R¹¹, R¹² and R¹³ may bond together to form a ring with the sulfur atom, L″ is a single bond or a straight C₁-C₂₀, branched or cyclic C₃-C₂₀ divalent hydrocarbon group which may be substituted with or separated by a heteroatom, q is 0 or 1, with the proviso that q is essentially 0 when L″ is a single bond.

In a preferred embodiment, the resist composition may further comprise a photoacid generator having the general formula (7) or (8).

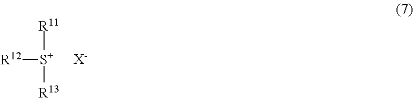

Herein R¹¹, R¹², R¹³, and X⁻ are as defined above.

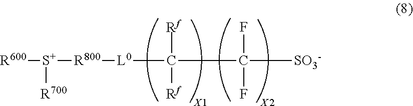

Herein x1, x2, and R^{f} are as defined above, L⁰ is a single bond or linking group, R⁶⁰⁰ and R⁷⁰⁰ are each independently a straight C₁-C₃₀, branched or cyclic C₃-C₃₀ monovalent hydrocarbon group which may be substituted with or separated by a heteroatom, R⁸⁰⁰ is a straight C₁-C₃₀, branched or cyclic C₃-C₃₀ divalent hydrocarbon group which may be substituted with or separated by a heteroatom, or any two or more of R⁶⁰⁰, R⁷⁰⁰, and R⁸⁰⁰ may bond together to form a ring with the sulfur atom.

In a preferred embodiment, the resist composition may further comprise a nitrogen-containing compound.

In a preferred embodiment, the resist composition may further comprise an onium salt having a structure represented by the general formula (9a) or (9b).

R^{q1}—SO₃⁻Mq⁺ (9a)

R^{q2}—CO₂⁻Mq⁺ (9b)

Herein R^{q1} is hydrogen or a straight C₁-C₄₀, branched or cyclic C₃-C₄₀ monovalent hydrocarbon group which may be substituted with or separated by a heteroatom, excluding that in formula (9a), a hydrogen atom on the α-position carbon atom relative to the sulfo group is substituted by fluorine or fluoroalkyl, R^{q2} is hydrogen or a straight C₁-C₄₀, branched or cyclic C₃-C₄₀ monovalent hydrocarbon group which may be substituted with or separated by a heteroatom, Mq⁺ is an onium cation having the general formula (c1), (c2) or (c3):

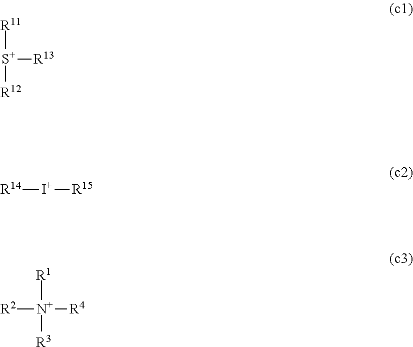

wherein R¹, R², R³, R⁴, R¹¹, R¹², and R¹³ are as defined above, R¹⁴ and R¹⁵ are each independently a straight, branched or cyclic C₁-C₁₀ alkyl or alkenyl group which may be substituted with or separated by a heteroatom, or a C₆-C₁₈ aryl group which may be substituted with or separated by a heteroatom.

In a preferred embodiment, the resist composition may further comprise a surfactant which is insoluble or substantially insoluble in water, but soluble in an alkaline developer and/or a surfactant which is insoluble or substantially insoluble in water and an alkaline developer.

In another aspect, the invention provides a process for forming a pattern, comprising the steps of coating the resist composition defined above onto a substrate, prebaking the coating to form a resist film, exposing the resist film through a photomask to KrF excimer laser, ArF excimer laser, EB or EUV, baking, and developing the resist film in a developer.

In a preferred embodiment, the exposure step is performed by immersion lithography while keeping a liquid having a refractive index of at least 1.0 between the resist film and a projection lens.

The process may further comprise the step of coating a protective film on the resist film, wherein the liquid is kept between the protective film and the projection lens.

### Advantageous Effects of Invention

When processed by high-energy lithography, especially ArF, EB or EUV lithography, the resist composition exhibits a high sensitivity and high resolution and is improved in LER.

### BRIEF DESCRIPTION OF DRAWINGS

FIG. 1 is a diagram showing the ¹H-NMR spectrum of the compound of Synthesis Example 1-1.

FIG. 2 is a diagram showing the ¹⁹F-NMR spectrum of the compound of Synthesis Example 1-1.

FIG. 3 is a diagram showing the ¹H-NMR spectrum of the compound of Synthesis Example 1-2.

FIG. 4 is a diagram showing the ¹⁹F-NMR spectrum of the compound of Synthesis Example 1-2.

FIG. 5 is a diagram showing the ¹H-NMR spectrum of the compound of Synthesis Example 1-3.

FIG. 6 is a diagram showing the ¹⁹F-NMR spectrum of the compound of Synthesis Example 1-3.

FIG. 7 is a diagram showing the ¹H-NMR spectrum of the compound of Synthesis Example 1-4.

FIG. 8 is a diagram showing the ¹⁹F-NMR spectrum of the compound of Synthesis Example 1-4.

### DESCRIPTION OF EMBODIMENTS

As used herein, the singular forms “a,” “an” and “the” include plural referents unless the context clearly dictates otherwise. “Optional” or “optionally” means that the subsequently described event or circumstances may or may not occur, and that description includes instances where the event or circumstance occurs and instances where it does not. The notation (Cn-Cm) means a group containing from n to m carbon atoms per group. In the chemical formulae, Me stands for methyl, and Ac for acetyl.

The acronym “PAG” stands for photoacid generator, “PEB” for post-exposure bake, “LER” for line edge roughness, “EUV” for extreme ultraviolet, and “EB” for electron beam.

Briefly stated, the resist composition is defined as comprising (A) a base resin comprising recurring units (A1) and (A2) and (B) an ammonium salt having the general formula (3).

### (A) Base Resin

The base resin essentially comprises recurring units (A1) having the general formula (1a) or (1b).

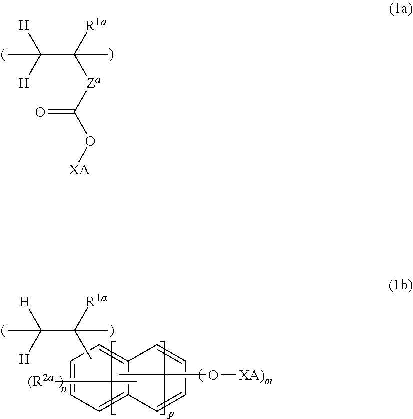

Herein R^{1a} is hydrogen, fluorine, methyl or trifluoromethyl, Z^{a} is a single bond or (backbone)-C(═O)—O—Z′—, Z′ is a straight C₁-C₁₀, branched or cyclic C₃-C₁₀ alkylene group which may contain a hydroxyl moiety, ether bond, ester bond or lactone ring, or phenylene or naphthylene group, XA is an acid labile group, R^{2a} is a straight C₁-C₁₀, branched or cyclic C₃-C₁₀ monovalent hydrocarbon group which may be substituted with or separated by a heteroatom, m is an integer of 1 to 3, n is an integer satisfying 0≦n≦5+2p−m, and p is 0 or 1. It is noted throughout the disclosure that the phrase “hydrocarbon group which may be substituted with or separated by a heteroatom” refers to a hydrocarbon group in which one or more or even all hydrogen atoms may be substituted by a heteroatom(s) or in which a heteroatom may intervene in a carbon-carbon bond.

In formula (1a), R^{1a} is hydrogen, fluorine, methyl or trifluoromethyl. Z^{a} is a single bond or (backbone)-C(═O)—O—Z′—. Z′ is a straight C₁-C₄₀, branched or cyclic C₃-C₁₀ alkylene group which may contain a hydroxyl moiety, ether bond, ester bond or lactone ring, or a phenylene or naphthylene group. XA is an acid labile group. The unit of formula (1a) is described and exemplified in JP-A 2014-225005, paragraphs [0014]-[0042] (U.S. Pat. No. 9,164,384). The preferred structure of formula (1a) is a tertiary ester structure containing an alicyclic group. Examples of the preferred structure are shown below, but not limited thereto.

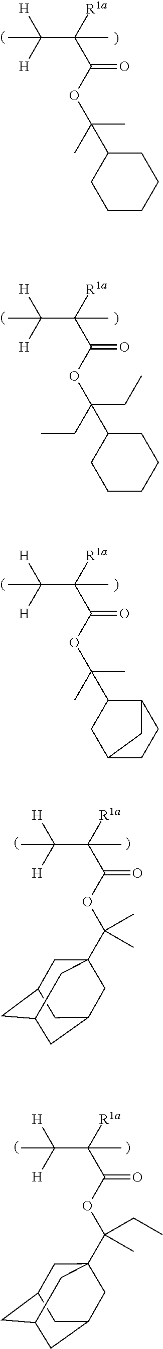

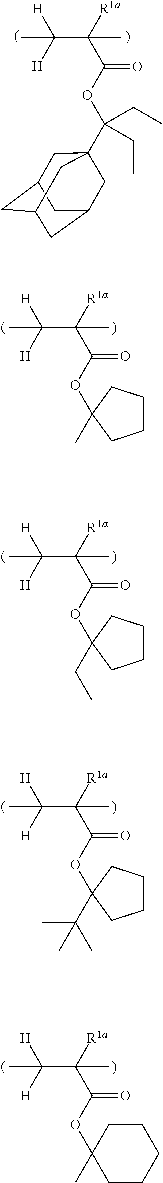

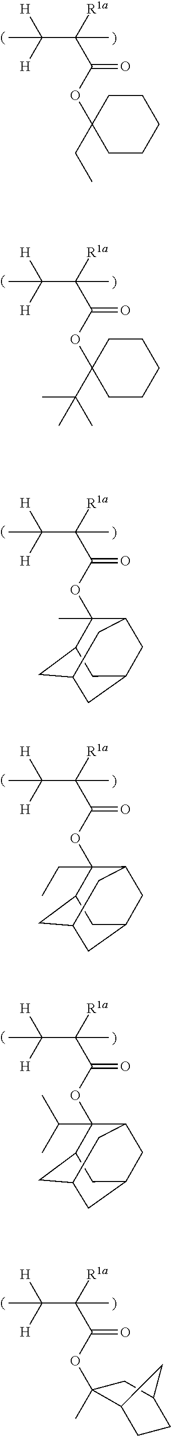

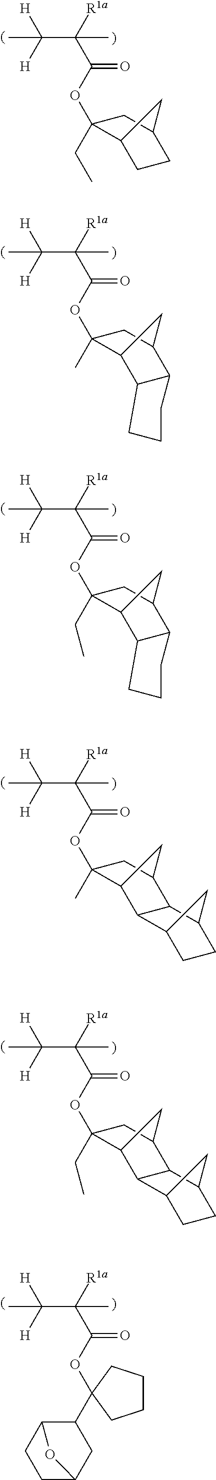

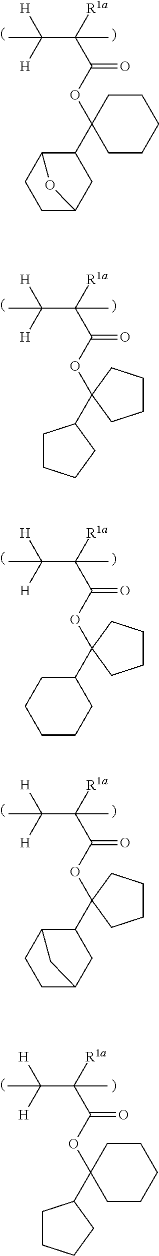

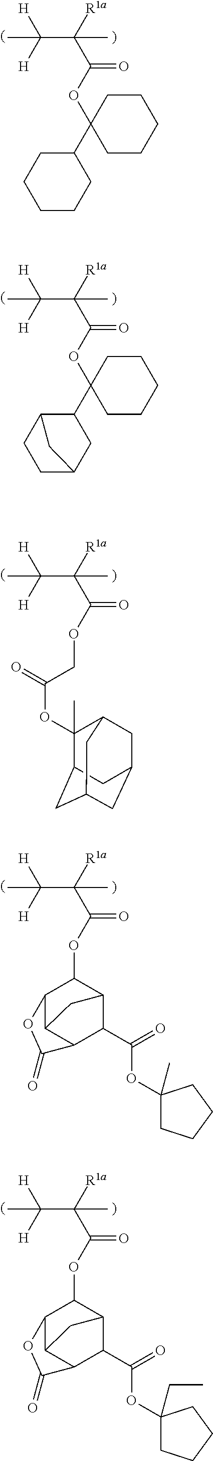

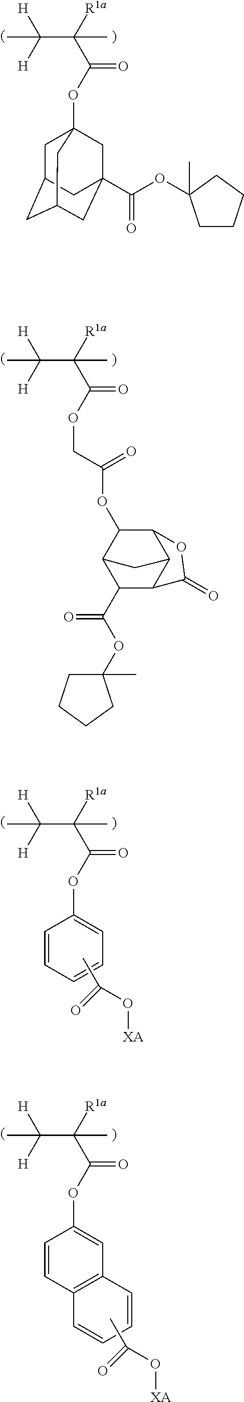

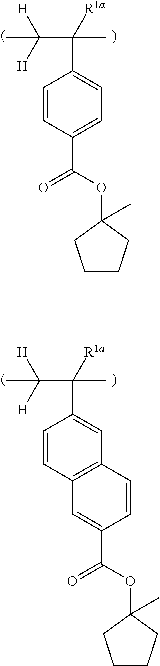

The recurring unit of formula (1a) is especially suited in the base resin application for the ArF, EB or EUV lithography.

In formula (1b), R^{1a} and XA are as defined above. R^{2a} is a straight C₁-C₁₀, branched or cyclic C₃-C₁₀ monovalent hydrocarbon group which may be substituted with or separated by a heteroatom, m is an integer of 1 to 3, n is an integer satisfying 0≦n≦5+2p−m, and p is 0 or 1. Preferably, n is 0, 1 or 2; m is 0 or 1; p is 0.

Examples of the monovalent hydrocarbon group represented by R^{2a} include methyl, ethyl, propyl, isopropyl, n-butyl, sec-butyl, tert-butyl, tert-pentyl, n-pentyl, n-hexyl, n-octyl, cyclopentyl, cyclohexyl, 2-ethylhexyl, cyclopentylmethyl, cyclopentylethyl, cyclohexylmethyl, cyclohexylethyl, norbornyl, oxanorbornyl, tricyclo[5.2.1.0^{2,6}]decanyl, adamantyl, phenyl and naphthyl. Also included are the foregoing groups in which at least one hydrogen atom is replaced by a heteroatom such as oxygen, sulfur, nitrogen or halogen, or in which a heteroatom such as oxygen, sulfur or nitrogen intervenes between carbon atoms, so that a hydroxyl radical, cyano radical, carbonyl radical, ether bond, ester bond, sulfonic acid ester bond, carbonate bond, lactone ring, sultone ring, carboxylic acid anhydride, or haloalkyl radical may form or intervene.

Preferred examples of the recurring unit having formula (1b) are shown below, but not limited thereto.

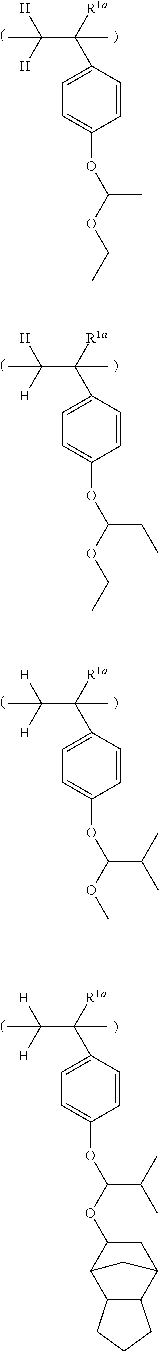

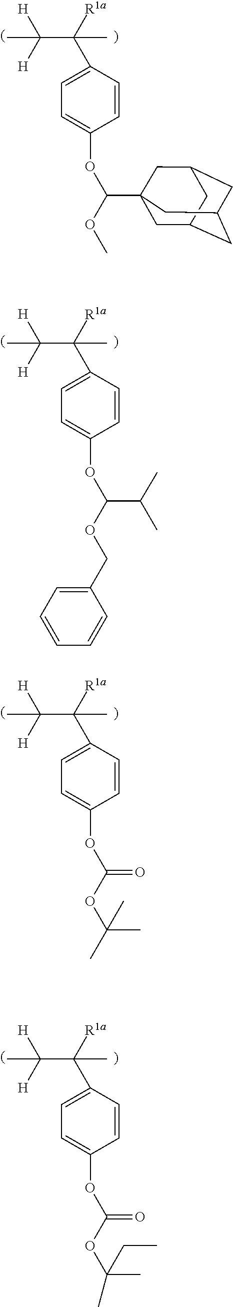

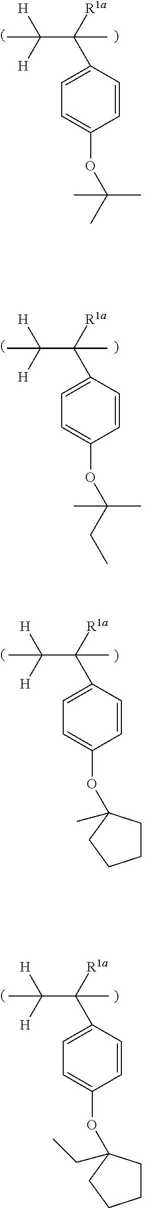

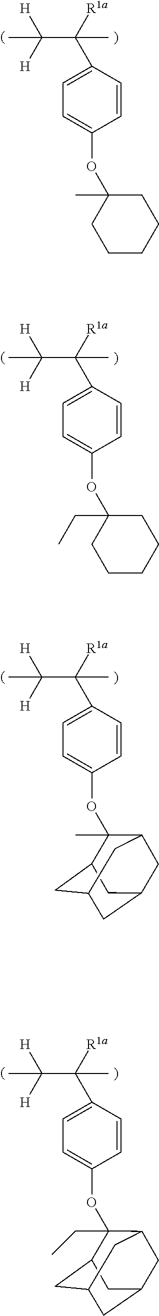

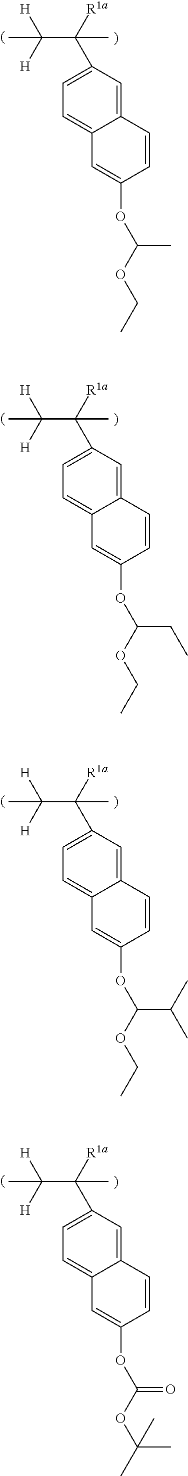

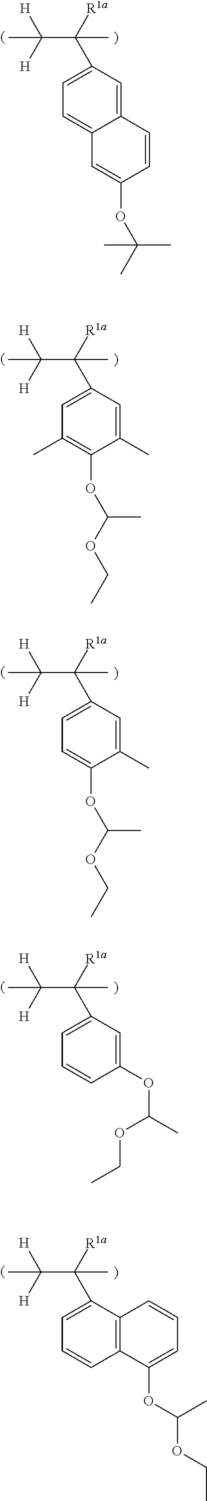

The recurring unit of formula (1b) is especially suited in the base resin application for the ArF, EB or EUV lithography, more preferably for the EB or EUV lithography.

The base resin further essentially comprises recurring units (A2) having the general formula (2a) or (2b).

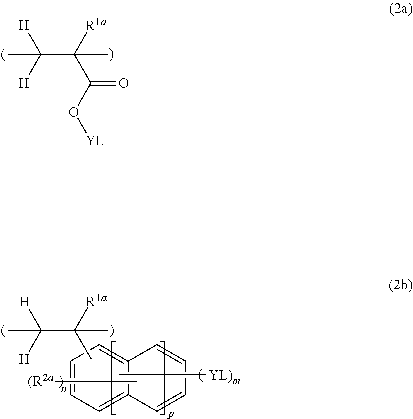

In formula (2a), R^{1a} is as defined above. YL is hydrogen or a polar group having at least one structure selected from the group consisting of hydroxyl, cyano, carbonyl, carboxyl, ether bond, ester bond, sulfonic acid ester bond, carbonate bond, lactone ring, sultone ring, and carboxylic anhydride. The unit of formula (2a) is described and exemplified in JP-A 2014-225005, paragraphs [0043]-[0054](U.S. Pat. No. 9,164,384). The preferred structure of formula (2a) is a lactone structure or phenol-containing structure. Preferred examples of the structure are shown below, but not limited thereto.

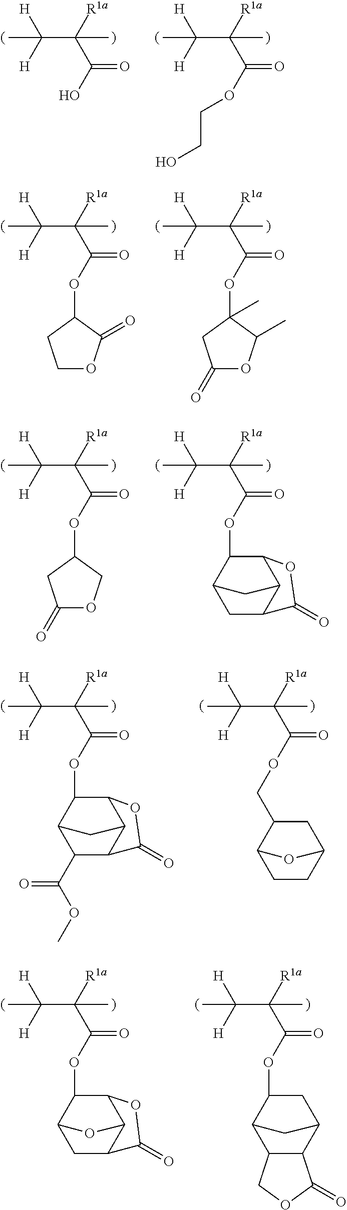

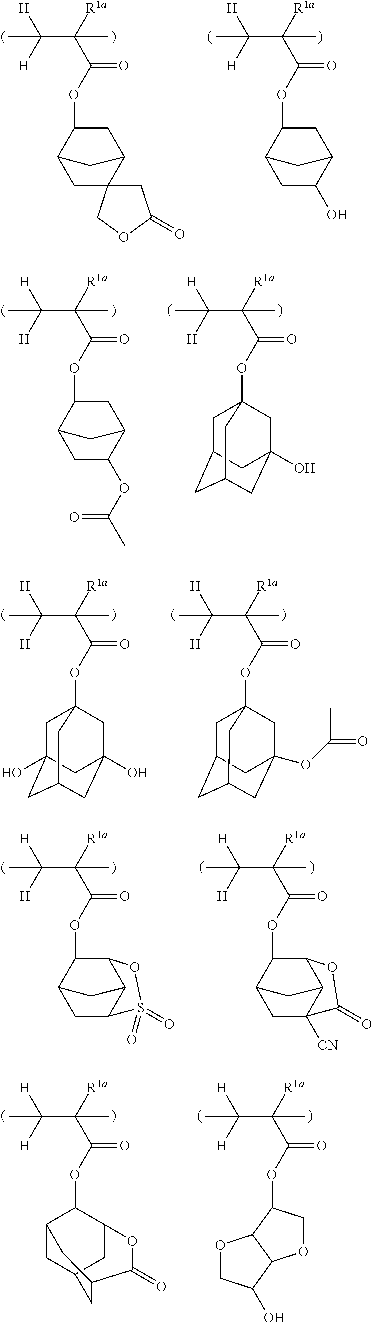

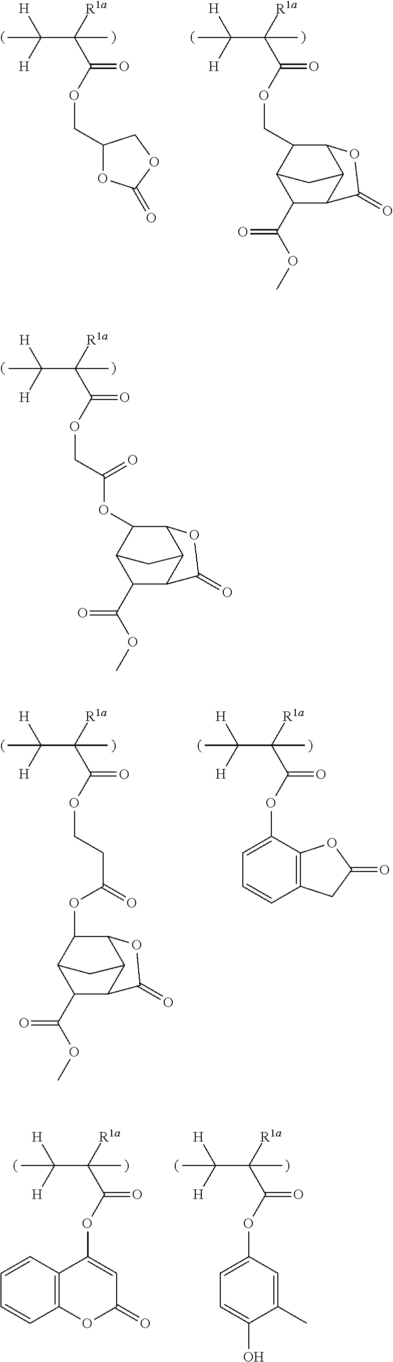

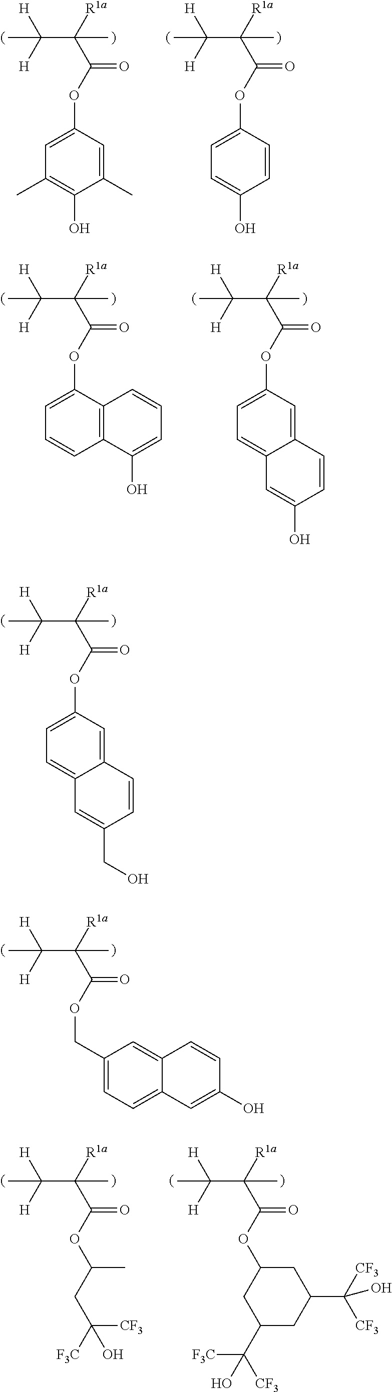

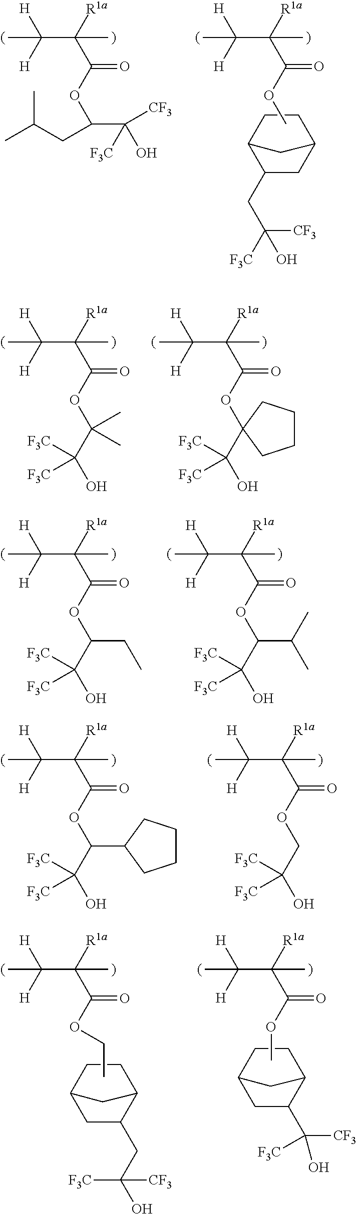

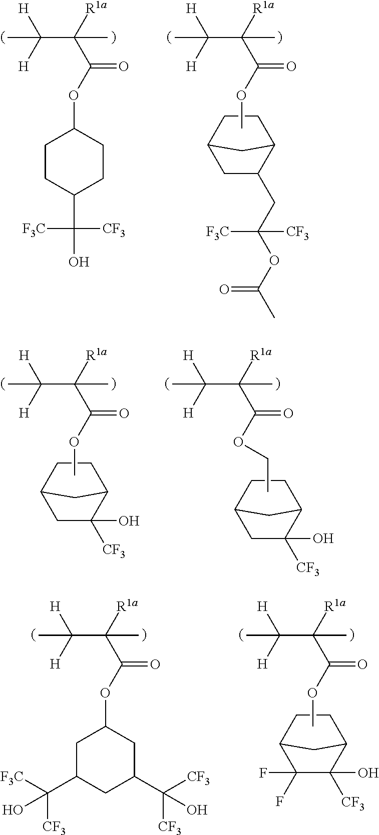

In formula (2b), R^{1a}, R^{2a}, m, n, p and YL are as defined above. Preferred examples of the structure having formula (2b) are shown below, but not limited thereto.

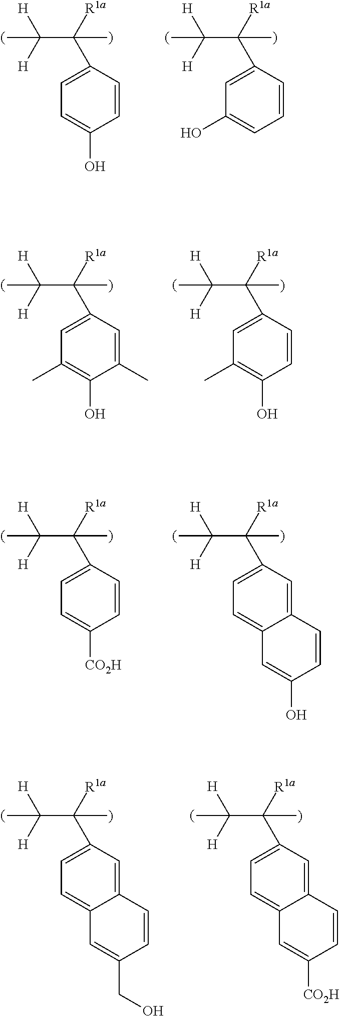

The recurring unit of formula (2b) is especially suited in the base resin application for the ArF, EB or EUV lithography, more preferably for the EB or EUV lithography.

In a preferred embodiment, the base resin further comprises recurring units having the general formula (6a) or (6b).

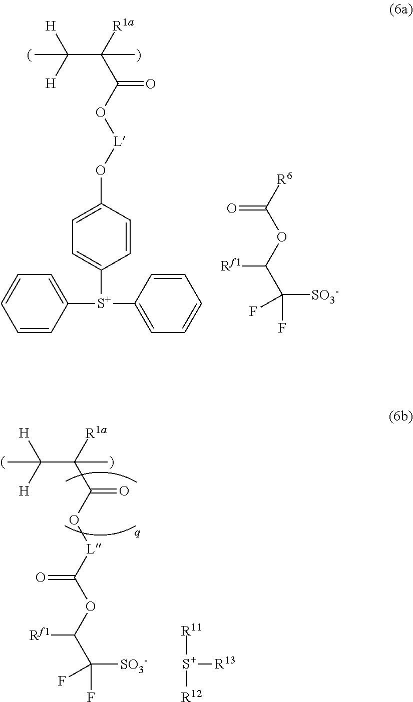

Herein R^{1a} is as defined above, R⁶ is a straight C₁-C₄₀, branched or cyclic C₃-C₄, monovalent hydrocarbon group which may be substituted with or separated by a heteroatom, R^{f1} is each independently hydrogen or trifluoromethyl, L′ is C₁-C₅ alkylene, R¹¹, R¹² and R¹³ are each independently a straight, branched or cyclic C₁-C₁₀ alkyl or alkenyl group which may be substituted with or separated by a heteroatom, or a C₆-C₁₈ aryl group which may be substituted with or separated by a heteroatom, or any two of R¹¹, R¹² and R¹³ may bond together to form a ring with the sulfur atom, L″ is a single bond or a straight C₁-C₂₀, branched or cyclic C₃-C₂₀ divalent hydrocarbon group which may be substituted with or separated by a heteroatom, q is 0 or 1, with the proviso that q is essentially 0 when L″ is a single bond.

In formula (6a), examples of the monovalent hydrocarbon group represented by R⁶ include methyl, ethyl, propyl, isopropyl, n-butyl, sec-butyl, tert-butyl, tert-pentyl, n-pentyl, n-hexyl, n-octyl, n-nonyl, n-decyl, cyclopentyl, cyclohexyl, 2-ethylhexyl, cyclopentylmethyl, cyclopentylethyl, cyclopentylbutyl, cyclohexylmethyl, cyclohexylethyl, cyclohexylbutyl, norbornyl, oxanorbornyl, tricyclo[5.2.1.0^{2,6}]decanyl, adamantyl, phenyl, naphthyl and anthracenyl. Also included are the foregoing groups in which at least one hydrogen atom is replaced by a heteroatom such as oxygen, sulfur, nitrogen or halogen, or in which a heteroatom such as oxygen, sulfur or nitrogen intervenes between carbon atoms, so that a hydroxyl radical, cyano radical, carbonyl radical, ether bond, ester bond, sulfonic acid ester bond, carbonate bond, lactone ring, sultone ring, carboxylic acid anhydride, or haloalkyl radical may form or intervene.

Exemplary of the structure of the anion moiety in formula (6a) are the anion moieties described in JP-A 2014-177407, paragraphs [0100] to [0101].

In formula (6b), examples of the divalent hydrocarbon group represented by L″ include linear alkane diyl groups such as methylene, ethylene, propane-1,3-diyl, butane-1,4-diyl, pentane-1,5-diyl, hexane-1,6-diyl, heptane-1,7-diyl, octane-1,8-diyl, nonane-1,9-diyl, decane-1,10-diyl, undecane-1,11-diyl, dodecane-1,12-diyl, tridecane-1,13-diyl, tetradecane-1,14-diyl, pentadecane-1,15-diyl, hexadecane-1,16-diyl, heptadecane-1,17-diyl; saturated cyclic hydrocarbon groups such as cyclopentanediyl, cyclohexanediyl, norbornanediyl, and adamantanediyl; and unsaturated cyclic hydrocarbon groups such as phenylene and naphthylene. Also included are the foregoing groups in which at least one hydrogen atom is replaced by an alkyl group such as methyl, ethyl, propyl, n-butyl or tert-butyl. Alternatively, in the foregoing groups, a heteroatom such as oxygen, sulfur or nitrogen intervenes between carbon atoms, so that a hydroxyl radical, cyano radical, carbonyl radical, ether bond, ester bond, sulfonic acid ester bond, carbonate bond, lactone ring, sultone ring, carboxylic acid anhydride or haloalkyl radical may form.

In formula (6b), examples of the alkyl, alkenyl and aryl groups represented by R¹¹, R¹² and R¹³ include methyl, ethyl, propyl, isopropyl, n-butyl, sec-butyl, tert-butyl, tert-pentyl, n-pentyl, n-hexyl, n-octyl, cyclopentyl, cyclohexyl, 2-ethylhexyl, cyclopentylmethyl, cyclopentylethyl, cyclohexylmethyl, cyclohexylethyl, norbornyl, oxanorbornyl, tricyclo[5.2.1.0^{2,6}]decanyl, adamantyl, phenyl and naphthyl. Also included are the foregoing groups in which at least one hydrogen atom is replaced by a heteroatom such as oxygen, sulfur, nitrogen or halogen, or in which a heteroatom such as oxygen, sulfur or nitrogen intervenes between carbon atoms, so that a hydroxyl radical, cyano radical, carbonyl radical, ether bond, ester bond, sulfonic acid ester bond, carbonate bond, lactone ring, sultone ring, carboxylic acid anhydride, or haloalkyl radical may form or intervene. Inter alia, optionally substituted arylene groups are preferred. Any two or more of R¹¹, R¹² and R¹³ may bond together to form a ring with the sulfur atom. Examples of the ring structure are shown below.

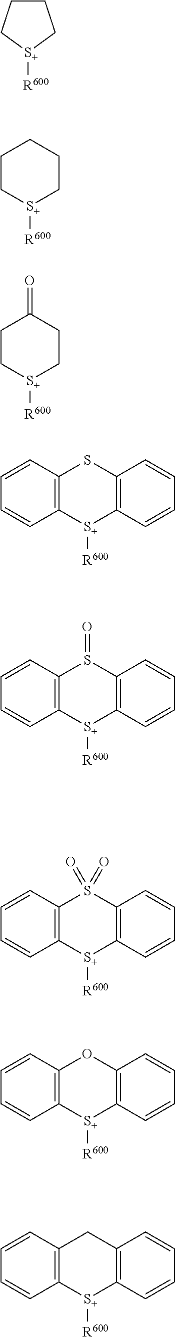

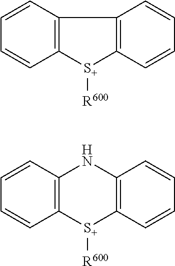

Herein R⁶⁰⁰ is a monovalent hydrocarbon group as defined and exemplified for R¹¹, R¹² and R¹³.

Exemplary structures of the sulfonium cation having formula (6b) are shown below, but not limited thereto.

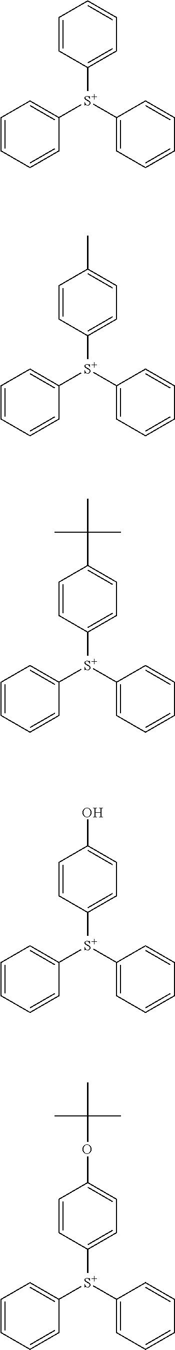 [SMILES: c1ccc([S+](c2ccccc2)c2ccccc2)cc1 ; Cc1ccc([S+](c2ccccc2)c2ccccc2)cc1 ; CC(C)(C)c1ccc([S+](c2ccccc2)c2ccccc2)cc1 ; Oc1ccc([S+](c2ccccc2)c2ccccc2)cc1 ; CC(C)(C)Oc1ccc([S+](c2ccccc2)c2ccccc2)cc1]

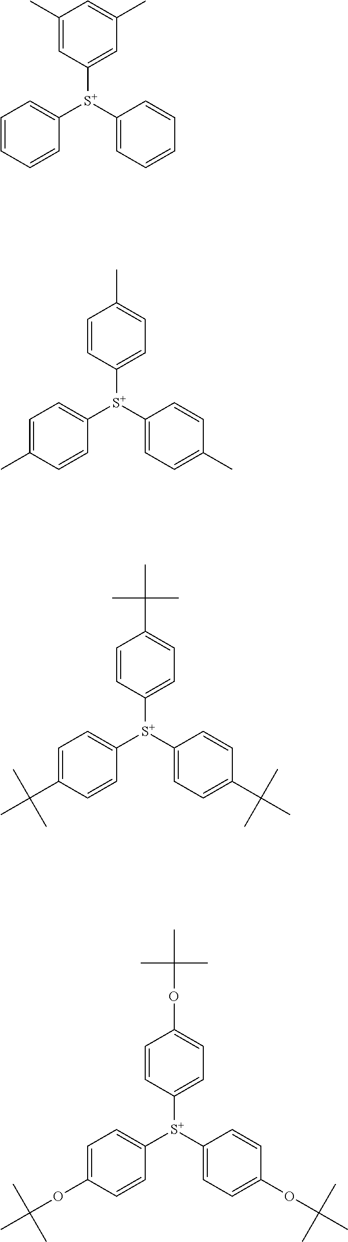

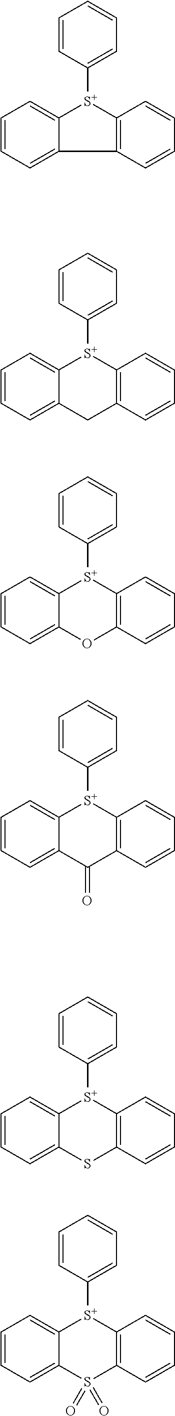 [SMILES: c1ccc(-[s+]2c3ccccc3c3ccccc32)cc1 ; c1ccc([S+]2c3ccccc3Cc3ccccc32)cc1 ; c1ccc([S+]2c3ccccc3Oc3ccccc32)cc1 ; O=c1c2ccccc2[s+](-c2ccccc2)c2ccccc12 ; c1ccc([S+]2c3ccccc3Sc3ccccc32)cc1 ; O=S1(=O)c2ccccc2[S+](c2ccccc2)c2ccccc21]

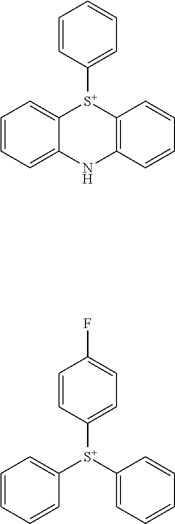 [SMILES: c1ccc([S+]2c3ccccc3Nc3ccccc32)cc1 ; Fc1ccc([S+](c2ccccc2)c2ccccc2)cc1]

Exemplary of the structure having formula (6b) are those described in JP-A 2010-077404, paragraphs [0021]-[0027] and JP-A 2010-116550, paragraphs [0021]-[0028].

In addition to recurring units (A1) and (A2) and optional units having formula (6a) or (6b), the base resin may have further copolymerized therein recurring units of the structure having a hydroxyl group protected with an acid labile group. The recurring unit of the structure having a hydroxyl group protected with an acid labile group is not particularly limited as long as it has one or more protected hydroxyl-bearing structure such that the protective group may be decomposed to generate a hydroxyl group under the action of acid. Examples of such recurring units are described in JP-A 2014-225005, paragraphs [0055] to [0065].

In addition to the foregoing units, the base resin may further comprise recurring units derived from other monomers, for example, substituted acrylic acid esters such as methyl methacrylate, methyl crotonate, dimethyl maleate and dimethyl itaconate, unsaturated carboxylic acids such as maleic acid, fumaric acid, and itaconic acid, cyclic olefins such as norbornene, norbornene derivatives, and tetracyclo[6.2.1.1^{3,6}.0^{2,7}]dodecene derivatives, unsaturated acid anhydrides such as itaconic anhydride, and other monomers. Also, hydrogenated ROMP polymers as described in JP-A 2003-066612 may be used.

The base resin or polymer preferably has a weight average molecular weight (Mw) of 1,000 to 500,000, and more preferably 3,000 to 100,000, as measured by gel permeation chromatography (GPC) versus polystyrene standards. Outside the range, there may result an extreme drop of etch resistance, and a drop of resolution due to difficulty to gain a dissolution rate difference before and after exposure.

The general method of synthesizing the base resin is, for example, by dissolving one or more unsaturated bond-bearing monomers in an organic solvent, adding a radical initiator, and effecting heat polymerization. Examples of the organic solvent which can be used for polymerization include toluene, benzene, tetrahydrofuran, diethyl ether and dioxane. Examples of the polymerization initiator used herein include 2,2′-azobisisobutyronitrile (AIBN), 2,2′-azobis(2,4-dimethylvaleronitrile), dimethyl 2,2-azobis(2-methylpropionate), benzoyl peroxide, and lauroyl peroxide. Preferably the reaction temperature is 50 to 80° C., and the reaction time is 2 to 100 hours, more preferably 5 to 20 hours. The acid labile group that has been incorporated in the monomer may be kept as such, or polymerization may be followed by protection or partial protection.

While the base resin (A) comprises recurring units derived from monomers, the molar fractions of respective units preferably fall in the following range (mol %), but are not limited thereto:
(I) 1 to 60 mol %, more preferably 5 to 50 mol %, even more preferably 10 to 50 mol % of constituent units (A1) of at least one type,
(II) 40 to 99 mol %, more preferably 50 to 95 mol %, even more preferably 50 to 90 mol % of constituent units (A2) of at least one type, and optionally,
(III) 0 to 30 mol %, more preferably 0 to 25 mol %, and even more preferably 0 to 20 mol % of constituent units of at least one type having formula (6a) or (6b), and optionally, (IV) 0 to 80 mol %, more preferably 0 to 70 mol %, and even more preferably 0 to 50 mol % of constituent units of at least one type derived from another monomer(s).

When constituent units having formula (6a) or (6b) are incorporated, their molar fraction is preferably at least 3 mol %, more preferably at least 5 mol %. The upper limit is the same as above. When constituent units having formula (6a) or (6b) are incorporated, the molar fraction of units (A1) and/or (A2), especially (A2) may be accordingly reduced.

### (B) Ammonium Salt

Also essentially, the resist composition comprises an ammonium salt having the general formula (3).

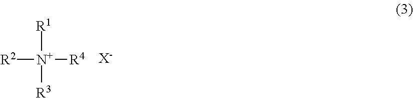

Herein R¹ to R⁴ are each independently a straight C₁-C₂₀, branched or cyclic C₃-C₂₀ monovalent hydrocarbon group which may be substituted with or separated by a heteroatom, any two or more of R¹ to R⁴ may bond together to form a ring with the nitrogen atom to which they are attached. X⁻ is a structure of the general formula (3a), (3b) or (3c):

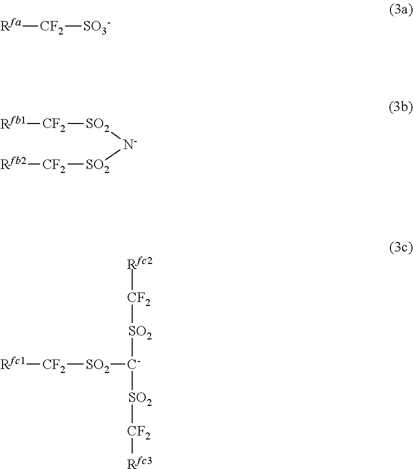

wherein R^{fa}, R^{fb1}, R^{fb2}, R^{fc1}, R^{fc2} and R^{fc3} are each independently fluorine or a straight C₁-C₄₀, branched or cyclic C₃-C₄₀ monovalent hydrocarbon group which may be substituted with or separated by a heteroatom, or a pair of R^{fb1} and R^{fb2}, or R^{fc1} and R^{fc2} may bond together to form a ring with the carbon atom to which they are attached and any intervening atoms.

In the cation moiety in formula (3), examples of the hydrocarbon group represented by R¹ to R⁴ include methyl, ethyl, propyl, isopropyl, n-butyl, sec-butyl, tert-butyl, tert-pentyl, n-pentyl, n-hexyl, n-octyl, n-nonyl, n-decyl, cyclopentyl, cyclohexyl, 2-ethylhexyl, cyclopentylmethyl, cyclopentylethyl, cyclopentylbutyl, cyclohexylmethyl, cyclohexylethyl, cyclohexylbutyl, norbornyl, oxanorbornyl, tricyclo[5.2.1.0^{2,6}]decanyl, adamantyl, phenyl, naphthyl and anthracenyl. Also included are the foregoing groups in which at least one hydrogen atom is replaced by a heteroatom such as oxygen, sulfur, nitrogen or halogen, or in which a heteroatom such as oxygen, sulfur or nitrogen intervenes between carbon atoms, so that a hydroxyl radical, cyano radical, carbonyl radical, ether bond, ester bond, sulfonic acid ester bond, carbonate bond, lactone ring, sultone ring, carboxylic acid anhydride, or haloalkyl radical may form or intervene. Those structures shown below are preferable because of availability, but the cation is not limited thereto.

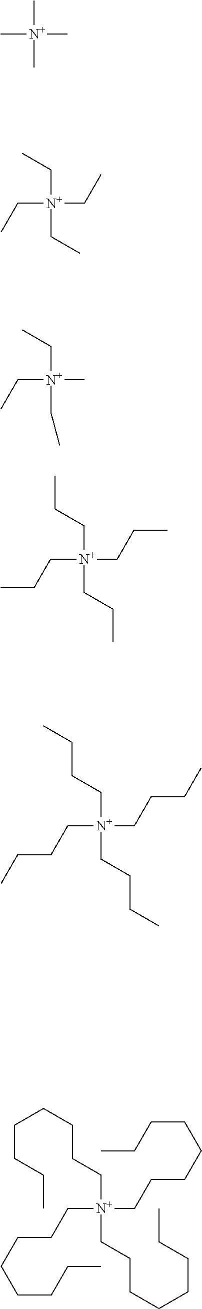

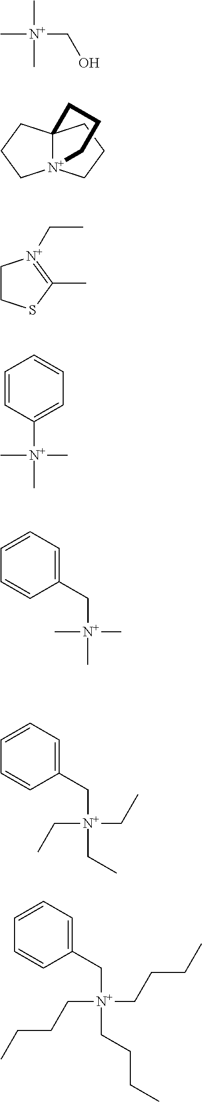

In formulae (3a), (3b) and (3c), the groups of R^{fa}, R^{fb1}, R^{fb2}, R^{fc1}, R^{fc2} and R^{fc3} are as exemplified for R¹ to R⁴. Specifically, examples of the sulfonate having formula (3a) include trifluoromethanesulfonate, pentafluoroethanesulfonate, nonafluorobutanesulfonate, dodecafluorohexanesulfonate, 2-benzoyloxy-1,1,3,3,3-pentafluoropropanesulfonate, 1,1,3,3,3-pentafluoro-2-(4-phenylbenzoyloxy)propanesulfonate, 1,1,3,3,3-pentafluoro-2-pivaloyloxypropanesulfonate, 2-cyclohexanecarbonyloxy-1,1,3,3,3-pentafluoropropanesulfonate, 2-naphthoyloxy-1, 1,3,3,3-pentafluoropropanesulfonate, 2-(4-tert-butylbenzoyloxy)-1,1,3,3,3-pentafluoropropanesulfonate, 2-adamantanecarbonyloxy-1,1,3,3,3-pentafluoropropanesulfonate, 2-acetyloxy-1,1,3,3,3-pentafluoroprop anesulfonate, 1,1,3,3,3-pentafluoro-2-hydroxypro panesulfonate, 1,1,3,3,3-pentafluoro-2-tosyloxypropanesulfonate, 1,1-difluoro-2-naphthylethanesulfonate, and 1,1,2,2-tetrafluoro-2-(norbornan-2-yl)ethanesulfonate.

Examples of the anion having formula (3b) include bistrifluoromethanesulfonylimide, bispentafluoroethanesulfonylimide, bisheptafluoropropanesulfonylimide, and 1,3-perfluoropropylenebissulfonylimide.

Typical of the anion having formula (3c) is tristrifluoromethanesulfonylmethide.

The ammonium salt (B) preferably has a structure represented by the general formula (4).

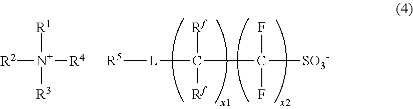

Herein R¹ to R⁴ are as defined above, R⁵ is a straight C₁-C₄₀, branched or cyclic C₃-C₄₀ monovalent hydrocarbon group which may be substituted with or separated by a heteroatom, R^{f} is each independently hydrogen, fluorine or fluoroalkyl, L is a single bond or linking group, x1 is an integer of 0 to 10, and x2 is an integer of 1 to 5.

Examples of the group R⁵ are as exemplified above for R¹ to R⁴. Exemplary of the linking group L are an ether bond, ester bond, thioether bond, sulfinic acid ester bond, sulfonic acid ester bond, carbonate bond, and carbamate bond.

More preferably, the ammonium salt (B) has a structure represented by the general formula (5).

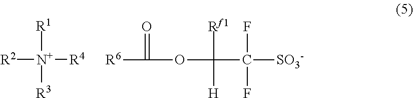

Herein R¹ to R⁴ are as defined above, R⁶ is a straight C₁-C₄₀, branched or cyclic C₃-C₄, monovalent hydrocarbon group which may be substituted with or separated by a heteroatom, and R^{f1} is each independently hydrogen or trifluoromethyl.

Examples of the group R⁶ are as exemplified above for R¹ to R⁴.

Preferred structures of the anion moiety in the ammonium salt (B) are shown below, but not limited thereto.

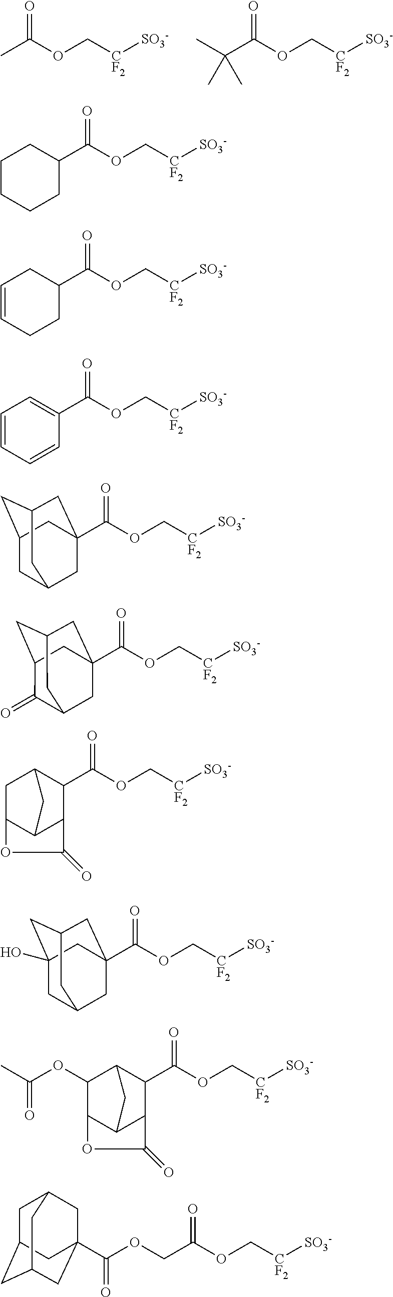

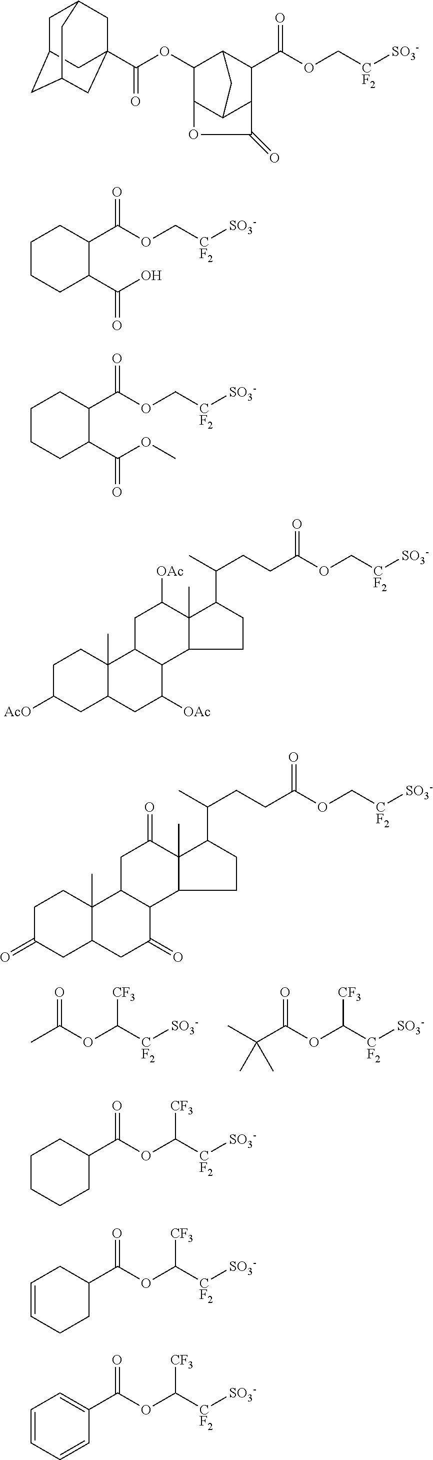

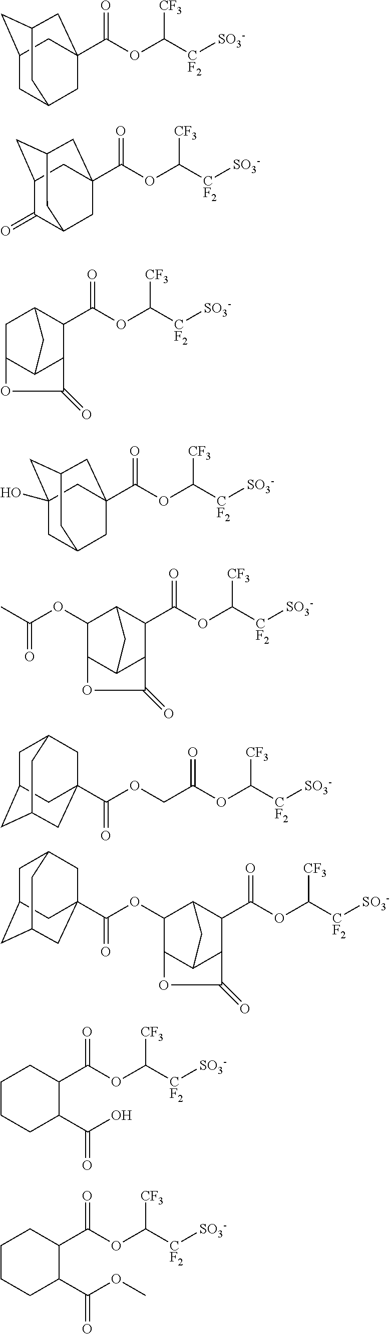

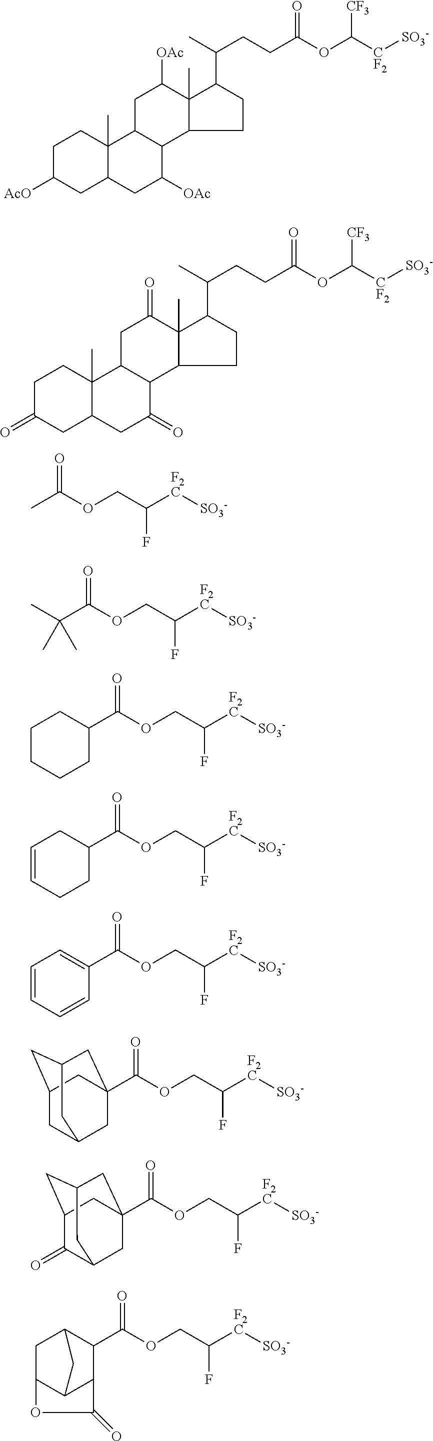

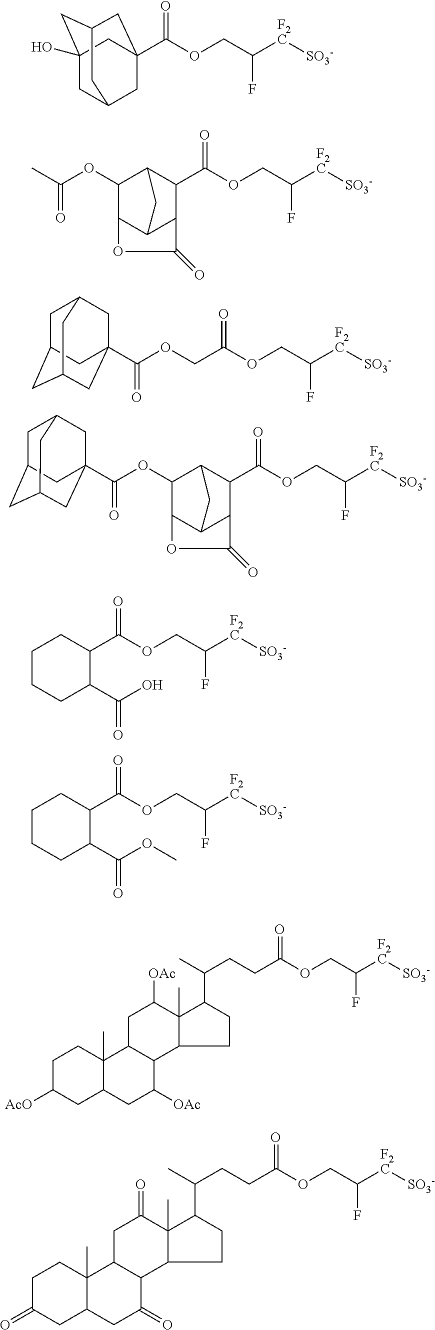

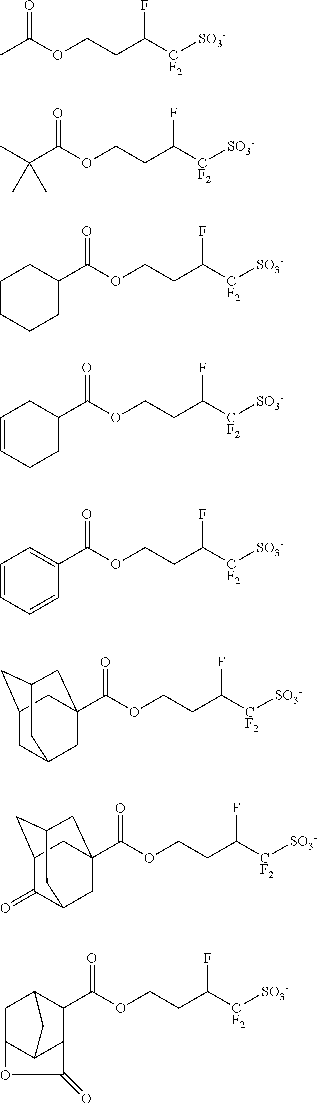

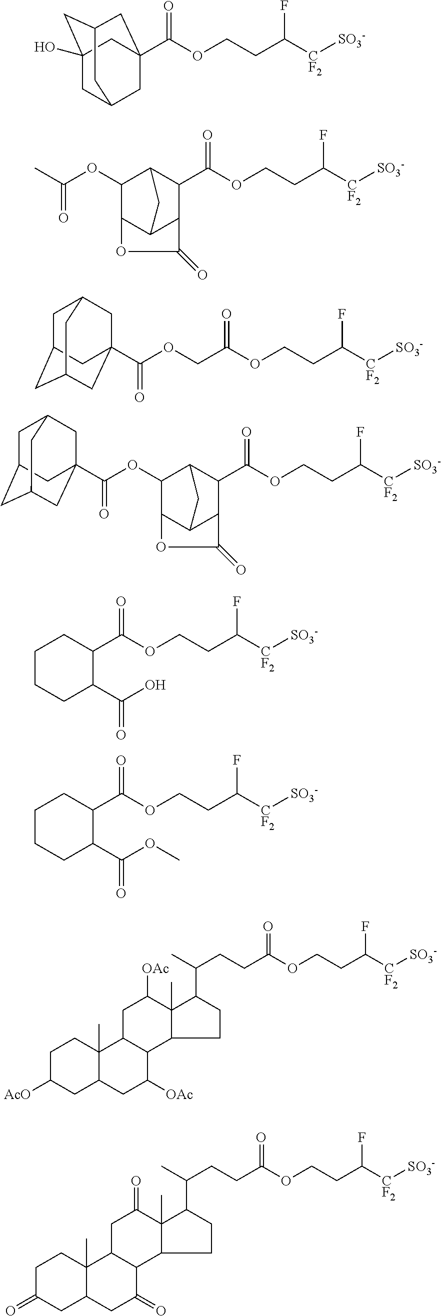

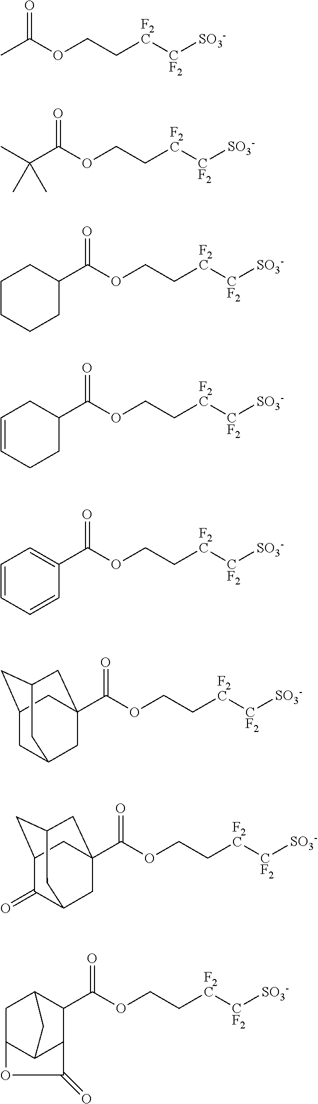

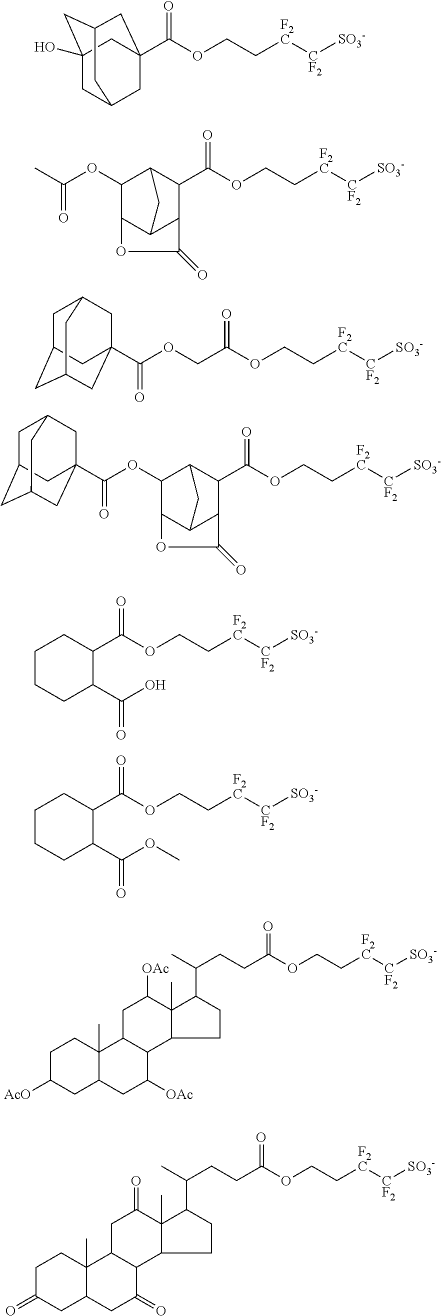

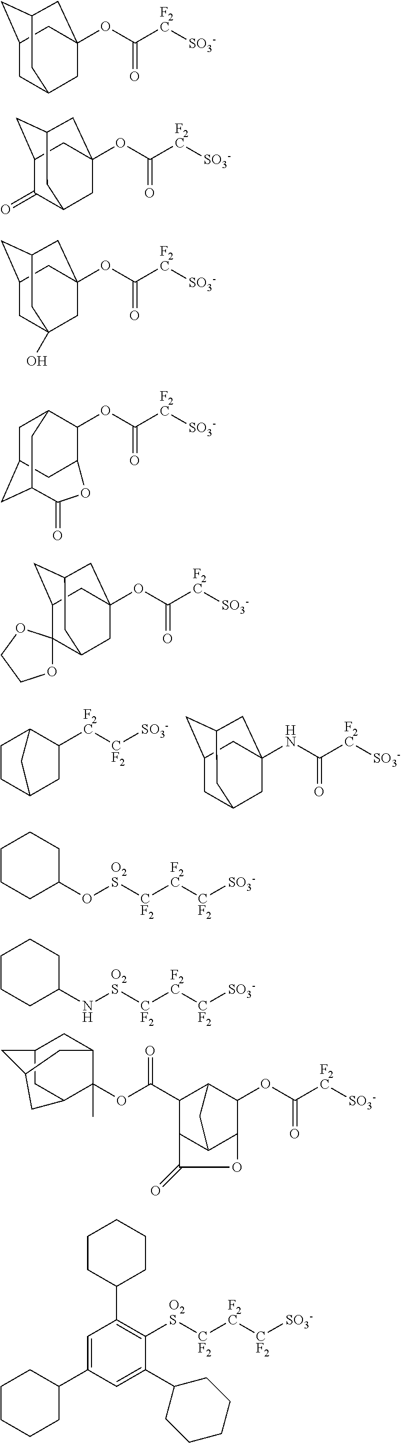

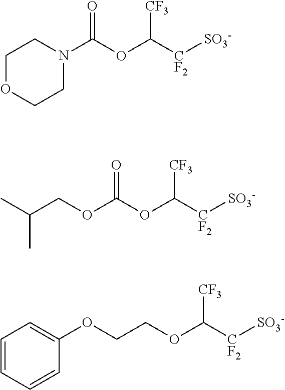

The ammonium salt (B) may be any of arbitrary combinations of cations with anions, both as exemplified above.

The ammonium salt (B) may be synthesized by any organic chemistry procedures well known to the artisan in the art. For example, the desired compound may be synthesized by mixing a cation-containing compound and an anion-containing compound in an organic solvent/water two-layer system, effecting ion exchange reaction therebetween, and extracting the organic layer. With respect to the ion exchange reaction, reference may be made to JP-A 2007-145797, for example. The cation moiety may be purchased in the market or synthesized by reaction of a tertiary amine compound with an alkyl halide, for example. The anion moiety may be purchased in the market or synthesized by any well-known procedures. In particular, with respect to the anion moiety of the compound having formula (5), reference may be made to JP-A 2007-145797 and JP-A 2009-258695, for example.

The resist composition of the invention is successful in improving several lithography properties, typically sensitivity and resolution while maintaining excellent LER.

Although the reason is not well understood, it is presumed that the addition of ammonium salt (B) has a good influence. Since the ammonium salt (B) has an anion structure which is a conjugated base of strong acid and a cation moiety which is a quaternary ammonium salt, it is not decomposed under the action of light or heat in the lithography process. As used herein, the strong acid refers to a compound having an acidity sufficient to cleave an acid labile group in the base resin. On the other hand, the PAG generates an acid upon exposure. It is believed that part of the generated acid undergoes salt exchange reaction with the ammonium salt (B). That is, the acid generated by the PAG acts on the ammonium salt at a different site, and the counter anion of the ammonium salt, in turn, generates a new acid. Presumably, this induces a moderate increase of acid diffusion length whereby sensitivity is improved. While an alternative approach of enhancing sensitivity by increasing the amount of PAG added is possible, this approach fails to fully control acid diffusion so that lithography properties, typically LER may be significantly degraded. The PAG used herein may be either incorporated in the base resin (i.e., polymer-bound PAG) or used as additive, with the polymer-bound PAG being preferred. By using the polymer-bound PAG to substantially suppress acid diffusion, and adding the ammonium salt (B) to compensate for a shortage of sensitivity and resolution, the lithography performance of a resist composition may be significantly improved.

An appropriate amount of the ammonium salt (B) added is 0.1 to 70 parts, preferably 0.5 to 50 parts, and more preferably 1 to 40 parts by weight per 100 parts by weight of the base resin. An excess of the ammonium salt may cause a degradation of resolution or leave foreign particles after resist development or stripping.

The resist composition of the invention comprises essentially (A) a base resin or polymer comprising recurring units (A1) and (A2) and (B) an ammonium salt having formula (3), as defined above, and optionally,

(C) a photoacid generator,

(D) a quencher,

(E) an organic solvent, and further optionally,

(F) a surfactant which is insoluble or substantially insoluble in water, but soluble in an alkaline developer and/or a surfactant which is insoluble or substantially insoluble in water and an alkaline developer.

### (C) Photoacid Generator

The resist composition preferably contains a photoacid generator (PAG). The PAG used herein is any compound capable of generating an acid upon exposure to high-energy radiation. Suitable PAGs include sulfonium salts, iodonium salts, sulfonyldiazomethane, N-sulfonyloxyimide, and oxime-O-sulfonate acid generators. They may be used alone or in admixture of two or more. Typical of the acid generated by PAG are strong acids such as α,α′-difluorosulfonic acid and (bisperfluoroalkanesulfonyl)imide, and (trisperfluoromethanesulfonyl)methide. Although it is preferred to use the PAG in the polymer-bound form as represented by formula (6a) or (6b), it is acceptable to blend the PAG as additive or to use both a polymer-bound PAG and a PAG additive.

Examples of the PAG include the compounds described in JP-A 2008-111103, paragraph [0122]-[0142] (U.S. Pat. No. 7,537,880). The more preferred structures are described in JP-A 2014-001259, paragraphs [0088]-[0092], JP-A 2012-041320, paragraphs [0015]-[0017], and JP-A 2012-106986, paragraphs [0015]-[0029].

An appropriate amount of the PAG (C) used is 0 to 40 parts, if added, preferably 0.1 to 40 parts, more preferably 0.1 to 20 parts by weight per 100 parts by weight of the base resin. An excess of the PAG may cause a degradation of resolution or leave foreign particles after resist development or stripping.

### (D) Quencher

Preferably (D) a quencher is added to the resist composition. As used herein, the “quencher” refers to a compound capable of suppressing the rate of diffusion when the acid generated by the PAG diffuses within the resist film.

In the relevant field, nitrogen-containing compounds are often used as the compound having such function and include primary, secondary and tertiary amine compounds. Suitable primary, secondary and tertiary amine compounds are described in JP-A 2008-111103, paragraphs [0146]-[0164] (U.S. Pat. No. 7,537,880), especially tertiary amine compounds having a hydroxyl group, ether bond, ester bond, lactone ring, cyano group or sulfonic acid ester bond being preferred. If some resist components are potentially unstable to strong bases such as tertiary alkyl amines, then weakly basic quenchers such as aniline compounds are preferred. For example, 2,6-diisopropylaniline and dialkylanilines are suitable. Also useful are compounds having primary or secondary amine protected as a carbamate group, as described in JP 3790649. Such protected amine compounds are effective when some resist components are unstable to bases.

The quencher may be used alone or in admixture of two or more. An appropriate amount of the quencher is 0.001 to 12 parts, preferably 0.01 to 8 parts by weight, per 100 parts by weight of the base resin. The inclusion of quencher facilitates adjustment of resist sensitivity and holds down the rate of acid diffusion within the resist film, resulting in better resolution. In addition, it suppresses changes in sensitivity following exposure and reduces substrate and environment dependence, as well as improving the exposure latitude and the pattern profile. The inclusion of quencher is also effective for improving adhesion to the substrate.

To the resist composition, an onium salt of a structure having the general formula (9a) or (9b) may be added if necessary. Like the above nitrogen-containing compound, this onium salt functions as a quencher.

R^{q1}—SO₃⁻Mq⁺ (9a)

R^{q2}—CO₂⁻Mq⁺ (9b)

Herein R^{q1} is hydrogen or a straight C₁-C₄₀, branched or cyclic C₃-C₄₀ monovalent hydrocarbon group which may be substituted with or separated by a heteroatom, excluding that in formula (9a), a hydrogen atom on the α-position carbon atom relative to the sulfo group is substituted by fluorine or fluoroalkyl. R^{q2} is hydrogen or a straight C₁-C₄₀, branched or cyclic C₃-C₄₀ monovalent hydrocarbon group which may be substituted with or separated by a heteroatom. Mq⁺ is an onium cation having the general formula (c1), (c2) or (c3).

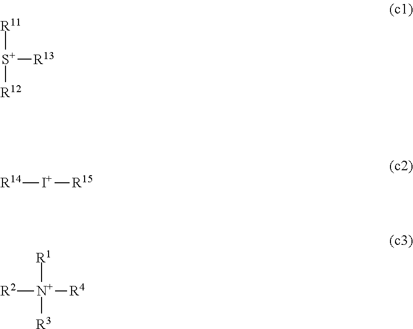

Herein R¹, R², R³, R⁴, R¹¹, R¹², and R¹³ are as defined above, R¹⁴ and R¹⁵ are each independently a straight, branched or cyclic C₁-C₁₀ alkyl or alkenyl group which may be substituted with or separated by a heteroatom, or a C₆-C₁₈ aryl group which may be substituted with or separated by a heteroatom.

In formula (9a), examples of the group R^{q1} include hydrogen, methyl, ethyl, propyl, isopropyl, n-butyl, sec-butyl, tert-butyl, tert-pentyl, n-pentyl, n-hexyl, n-octyl, n-nonyl, n-decyl, cyclopentyl, cyclohexyl, 2-ethylhexyl, cyclopentylmethyl, cyclopentylethyl, cyclopentylbutyl, cyclohexylmethyl, cyclohexylethyl, cyclohexylbutyl, norbornyl, oxanorbornyl, tricyclo[5.2.1.0^{2,6}]decanyl, adamantyl, phenyl, naphthyl and anthracenyl. Also included are the foregoing groups in which at least one hydrogen atom is replaced by a heteroatom such as oxygen, sulfur, nitrogen or halogen, or in which a heteroatom such as oxygen, sulfur or nitrogen intervenes between carbon atoms, so that a hydroxyl radical, cyano radical, carbonyl radical, ether bond, ester bond, sulfonic acid ester bond, carbonate bond, lactone ring, sultone ring, carboxylic acid anhydride, or haloalkyl radical may form or intervene.

In formula (9b), examples of the group R^{q2} include those exemplified above for R^{q1} and fluorinated alkyl groups such as trifluoromethyl and trifluoroethyl, and fluorinated aryl groups such as pentafluorophenyl and 4-trifluoromethylphenyl.

Illustrative structures of the anion moiety in formulae (9a) and (9b) are shown below, but not limited thereto.

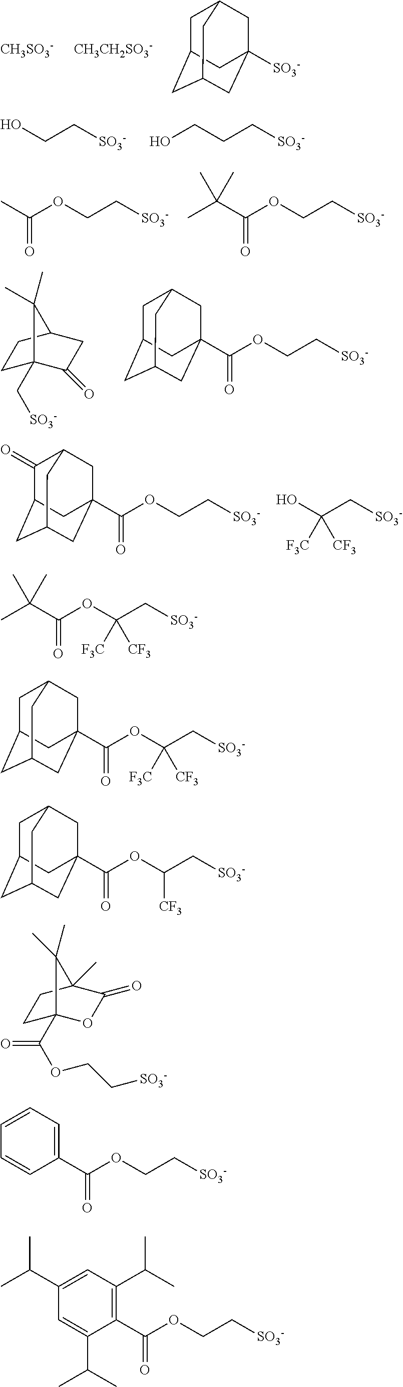

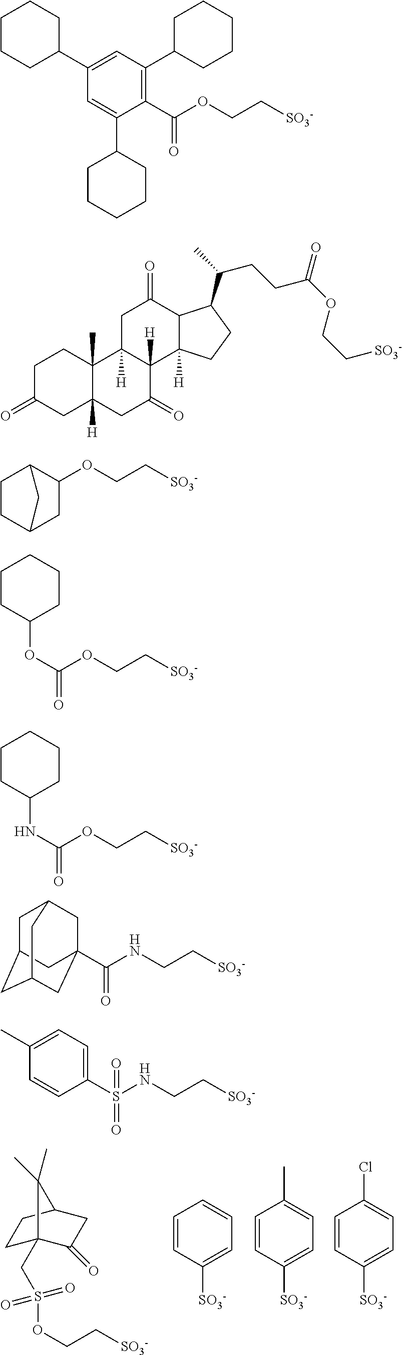

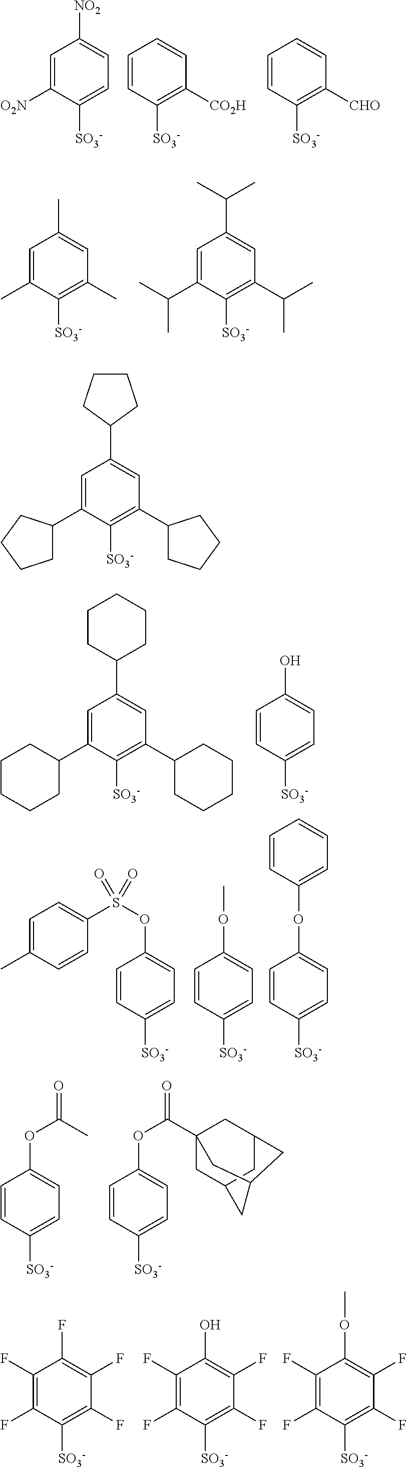

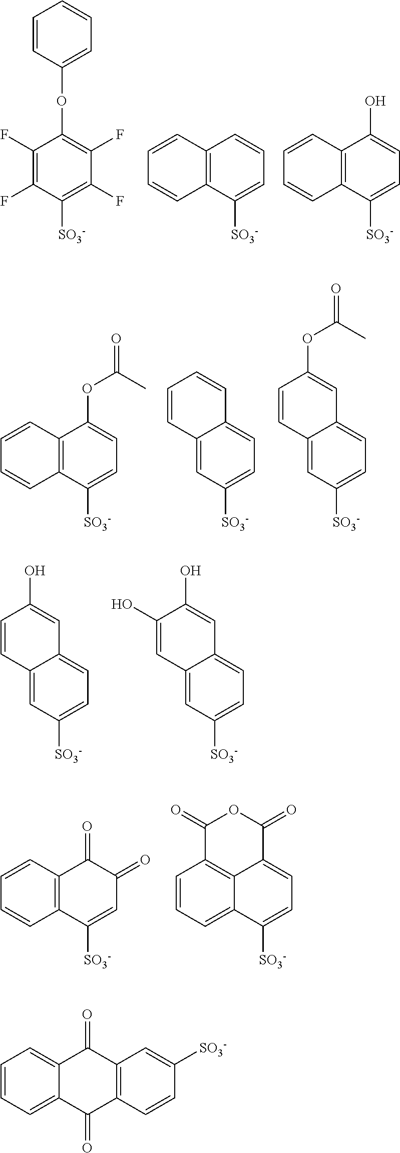

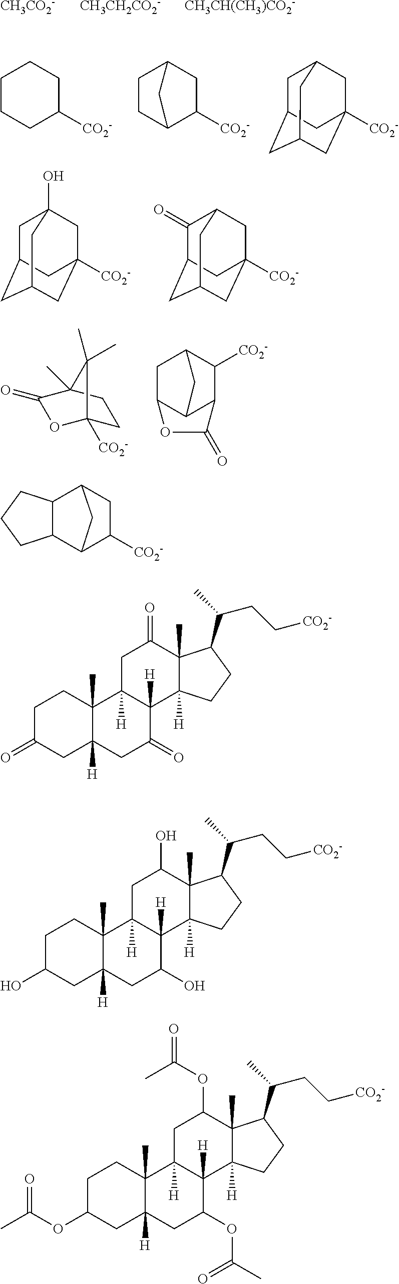

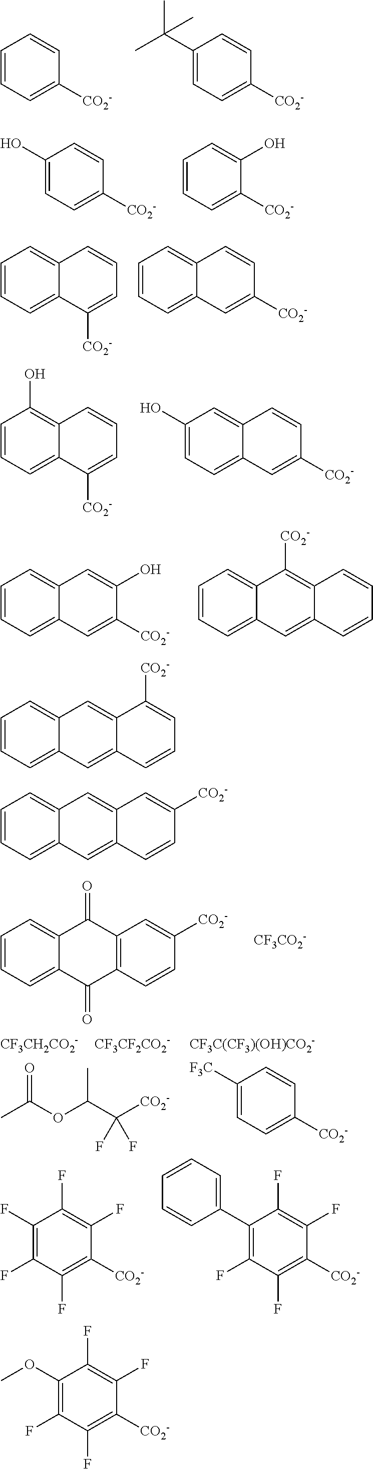

In formula (c2), examples of the groups R¹⁴ and R¹⁵ include the same monovalent hydrocarbon groups as exemplified for R^{q2} in formula (9b).

Illustrative structures of the cation moiety Mq⁺ in formulae (9a) and (9b) are shown below, but not limited thereto.

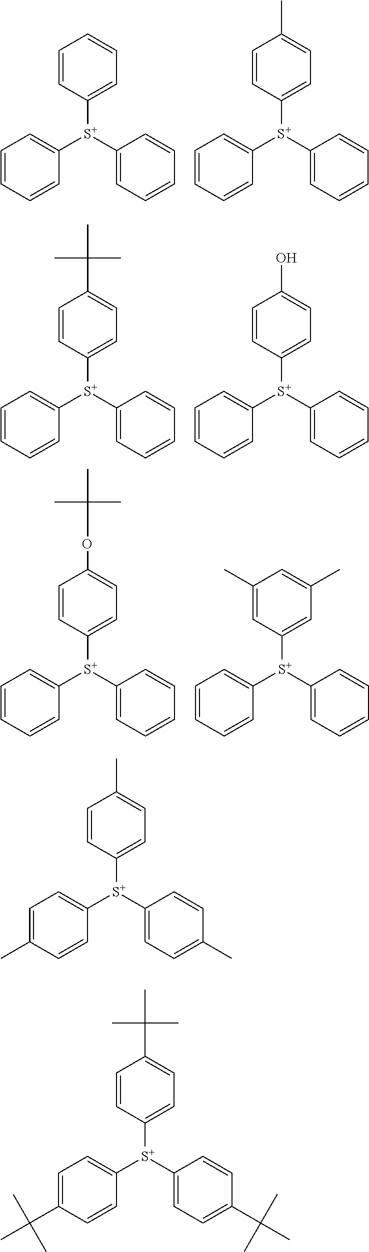

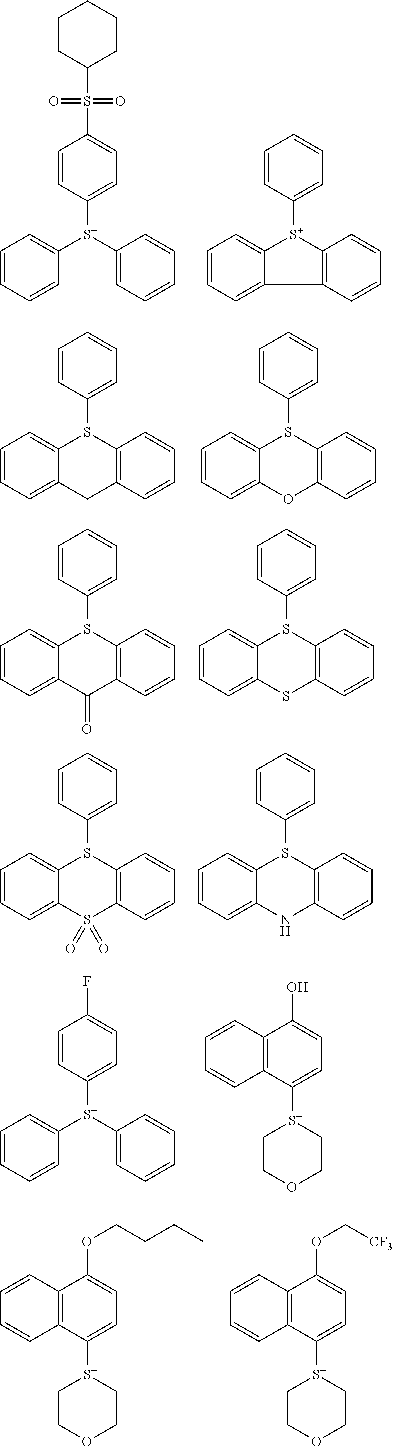

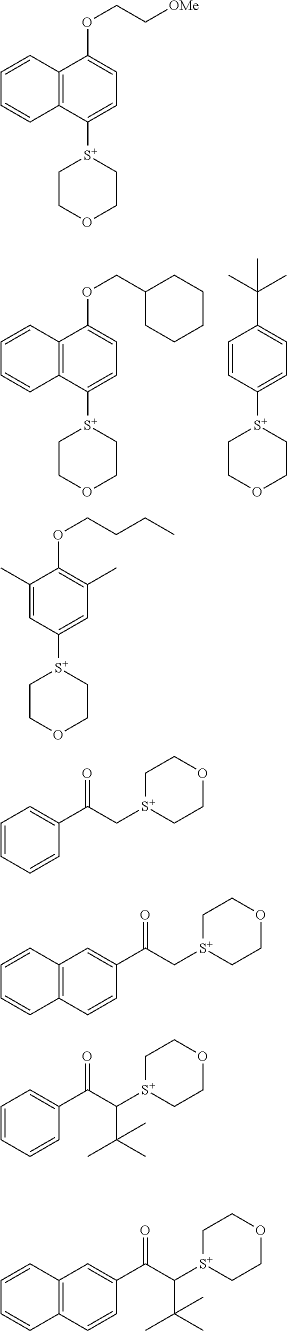

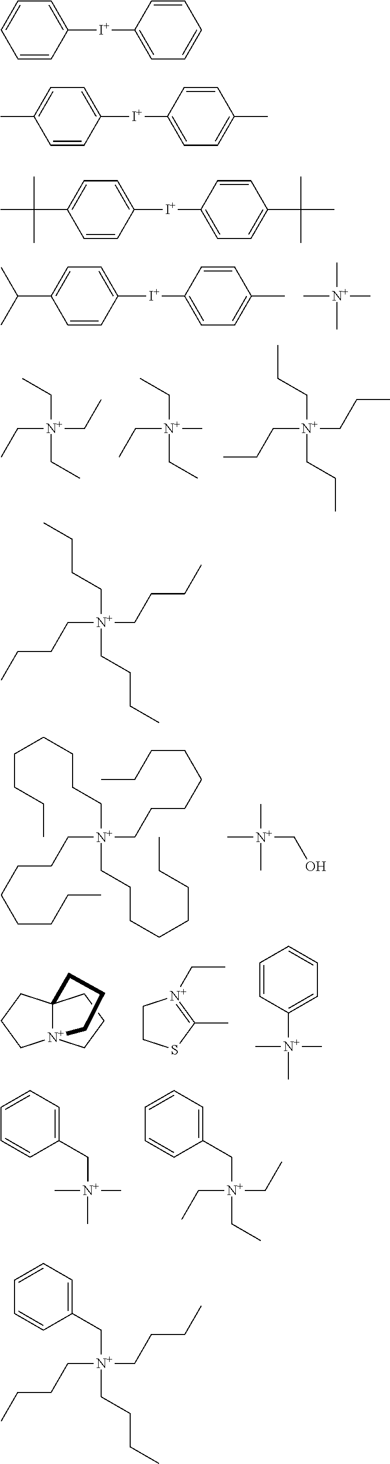

The onium salt having formula (9a) or (9b) may be any of arbitrary combinations of cations with anions, both as exemplified above. The onium salt may be readily synthesized by ion exchange reaction according to the well-known organic chemistry procedure. With respect to the ion exchange reaction, reference may be made to JP-A 2007-145797, for example.

In the resist application, the onium salt having formula (9a) or (9b) functions as the quencher or acid diffusion regulator. This is because the counter anion of the onium salt is a conjugated base of weak acid. As used herein, the “weak acid” indicates an acidity insufficient to deprotect an acid labile group from an acid labile group-containing unit in the base resin. The onium salt having formula (9a) or (9b) functions as a quencher when used in combination with an onium salt type PAG having a conjugated base of a strong acid, typically a sulfonic acid which is fluorinated at α-position as the counter anion. In a system using a mixture of an onium salt capable of generating a strong acid (e.g., α-position fluorinated sulfonic acid) and an onium salt capable of generating a weak acid (e.g., α-position non-fluorinated sulfonic acid or carboxylic acid), if the strong acid generated from the PAG upon exposure to high-energy radiation collides with the unreacted onium salt having a weak acid anion, then a salt exchange occurs whereby the weak acid is released and an onium salt having a strong acid anion is formed. In this course, the strong acid is exchanged into the weak acid having a low catalysis, incurring apparent deactivation of the acid for enabling to control acid diffusion. In this way, the onium salt having formula (9a) or (9b) functions as the quencher.

If a PAG capable of generating a strong acid is an onium salt, an exchange from the strong acid generated upon exposure to high-energy radiation to a weak acid as above can take place, but it rarely happens that the weak acid generated upon exposure to high-energy radiation collides with the unreacted onium salt capable of generating a strong acid to induce a salt exchange. This is because of a likelihood of an onium cation forming an ion pair with a stronger acid anion.

An appropriate amount of the onium salt having formula (9a) or (9b) added is 0 to 40 parts, and if used, preferably 0.1 to 40 parts, and more preferably 0.1 to 20 parts by weight per 100 parts by weight of the base resin. An excess of the onium salt may cause a degradation of resolution or leave foreign particles after resist development or stripping.

In the resist composition, a photo-decomposable onium salt having a nitrogen-containing substituent group may also be used together, if desired. This compound functions as a quencher in the unexposed region, but as a so-called photo-degradable base in the exposed region because it loses the quencher function in the exposed region due to neutralization thereof with the acid generated by itself. Using a photo-degradable base, the contrast between exposed and unexposed regions can be further enhanced. With respect to the photo-degradable base, reference may be made to JP-A 2009-109595, 2012-046501 and JP-A 2013-209360, for example.

An appropriate amount of the photo-degradable base added is 0 to 40 parts, and if used, preferably 0.1 to 40 parts, and more preferably 0.1 to 20 parts by weight per 100 parts by weight of the base resin. An excess of the base may cause a degradation of resolution or leave foreign particles after resist development or stripping.

### (E) Organic Solvent

Component (E) may be any organic solvent as long as the polymer, PAG, quencher and other additives are soluble therein. Examples of the organic solvent include ketones such as cyclohexanone and methyl-2-n-pentyl ketone; alcohols such as 3-methoxybutanol, 3-methyl-3-methoxybutanol, 1-methoxy-2-propanol, 1-ethoxy-2-propanol, and diacetone alcohol; ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; and lactones such as γ-butyrolactone, and mixtures thereof. Where an acid labile group of acetal form is used, a high-boiling alcohol solvent such as diethylene glycol, propylene glycol, glycerol, 1,4-butanediol or 1,3-butanediol may be added for accelerating deprotection reaction of acetal. Of the above organic solvents, it is recommended to use 1-ethoxy-2-propanol, PGMEA, cyclohexanone, γ-butyrolactone, and mixtures thereof because the acid generator is most soluble therein.

An appropriate amount of the organic solvent used is 200 to 7,000 parts, more preferably 400 to 5,000 parts by weight per 100 parts by weight of the base resin.

### (F) Surfactant

Component (F) is a surfactant which is insoluble or substantially insoluble in water and soluble in alkaline developer, and/or a surfactant which is insoluble or substantially insoluble in water and alkaline developer (hydrophobic resin). For the surfactant (F) which can be added to the resist composition, reference should be made to those compounds described in JP-A 2010-215608 and JP-A 2011-016746.

While many examples of the surfactant which is insoluble or substantially insoluble in water and alkaline developer are described in these patent documents, preferred examples are FC-4430, Surflon S-381, Surfynol E1004, KH-20 and KH-30, which may be used alone or in admixture. Partially fluorinated oxetane ring-opened polymers having the structural formula (surf-1) are also useful.

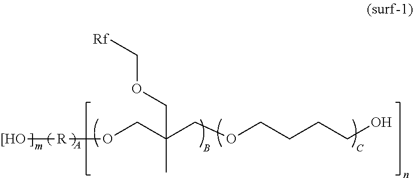

It is provided herein that R, Rf, A, B, C, m, and n are applied to only formula (surf-1), independent of their descriptions other than for the surfactant. R is a di- to tetra-valent C₂-C₅ aliphatic group. Exemplary divalent groups include ethylene, 1,4-butylene, 1,2-propylene, 2,2-dimethyl-1,3-propylene and 1,5-pentylene. Exemplary tri- and tetra-valent groups are shown below.

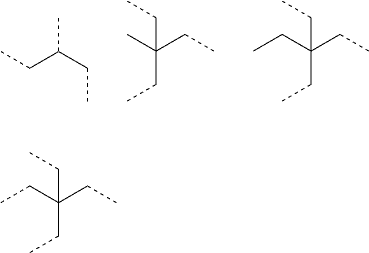

Herein the broken line denotes a valence bond. These formulae are partial structures derived from glycerol, trimethylol ethane, trimethylol propane, and pentaerythritol, respectively. Of these, 1,4-butylene and 2,2-dimethyl-1,3-propylene are preferably used.

Rf is trifluoromethyl or pentafluoroethyl, and preferably trifluoromethyl. The letter m is an integer of 0 to 3, n is an integer of 1 to 4, and the sum of m and n, which represents the valence of R, is an integer of 2 to 4. A is equal to 1, B is an integer of 2 to 25, and C is an integer of 0 to 10. Preferably, B is an integer of 4 to 20, and C is 0 or 1. Note that the above structural formula does not prescribe the arrangement of respective constituent units while they may be arranged either blockwise or randomly. For the preparation of surfactants in the form of partially fluorinated oxetane ring-opened polymers, reference should be made to U.S. Pat. No. 5,650,483, for example.

The surfactant which is insoluble or substantially insoluble in water and soluble in alkaline developer is useful when ArF immersion lithography is applied to the resist composition in the absence of a resist protective film. In this embodiment, the surfactant has a propensity to segregate on the resist surface after spin coating for achieving a function of minimizing water penetration or leaching. The surfactant is also effective for preventing water-soluble components from being leached out of the resist film for minimizing any damage to the exposure tool. The surfactant becomes solubilized during alkaline development following exposure and PEB, and thus forms few or no foreign particles which become defects. The preferred surfactant is a polymeric surfactant which is insoluble or substantially insoluble in water, but soluble in alkaline developer, also referred to as “hydrophobic resin” in this sense, and especially which is water repellent and enhances water slippage. Suitable polymeric surfactants are shown below.

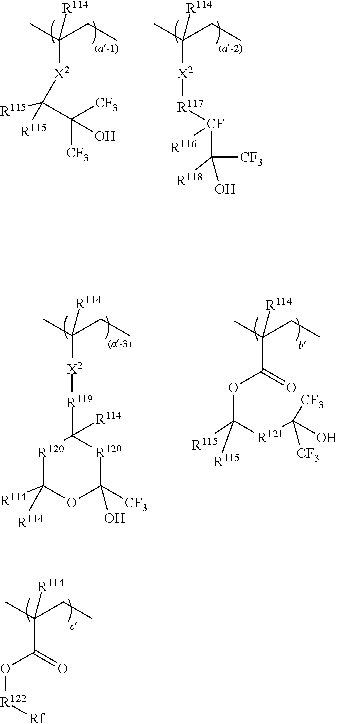

Herein R¹¹⁴ is each independently hydrogen, fluorine, methyl or trifluoromethyl. R¹¹⁸ is each independently hydrogen or a straight, branched or cyclic C₁-C₂₀ alkyl or fluoroalkyl group, or two R¹¹⁵ in a common monomer may bond together to form a ring with the carbon atom to which they are attached, and in this event, they together represent a straight, branched or cyclic C₂-C₂₀ alkylene or fluoroalkylene group. R¹¹⁶ is fluorine or hydrogen, or R¹¹⁶ may bond with R¹¹⁷ to form a non-aromatic ring of 3 to 10 carbon atoms in total with the carbon atom to which they are attached. R¹¹⁷ is a straight, branched or cyclic C₁-C₅ alkylene group in which at least one hydrogen atom may be substituted by a fluorine atom. R¹¹⁸ is a straight or branched C₁-C₁₀ alkyl group in which at least one hydrogen atom is substituted by a fluorine atom. Alternatively, R¹¹⁷ and R¹¹⁸ may bond together to form a non-aromatic ring with the carbon atoms to which they are attached. In this event, R¹¹⁷, R¹¹⁸ and the carbon atoms to which they are attached together represent a trivalent organic group of 2 to 12 carbon atoms in total. R¹¹⁹ is a single bond or a C₁-C₄ alkylene. R¹²⁰ is each independently a single bond, —O—, or —CR¹¹⁴R¹¹⁴—. R¹²¹ is a straight or branched C₁-C₄ alkylene group, or may bond with R¹¹⁵ within a common monomer to form a C₃-C₆ non-aromatic ring with the carbon atom to which they are attached. R¹²² is 1,2-ethylene, 1,3-propylene, or 1,4-butylene. Rf is a linear perfluoroalkyl group of 3 to 6 carbon atoms, typically 3H-perfluoropropyl, 4H-perfluorobutyl, 5H-perfluoropentyl, or 6H-perfluorohexyl. X² is each independently —C(═O)—O—, —O—, or —C(═O)—R¹²³—C(═O)—O—. R¹²³ is a straight, branched or cyclic C₁-C₁₀ alkylene group. The subscripts are in the range:
0≦(a′−1)<1, 0≦(a′−2)<1, 0≦(a′−3)<1,
0<(a′−1)+(a′−2)+(a′−3)<1, 0≦b′<1, 0≦c′<1, and
0<(a′−1)+(a′−2)+(a′−3)+b′+c′≦1.

Examples of these units are shown below.

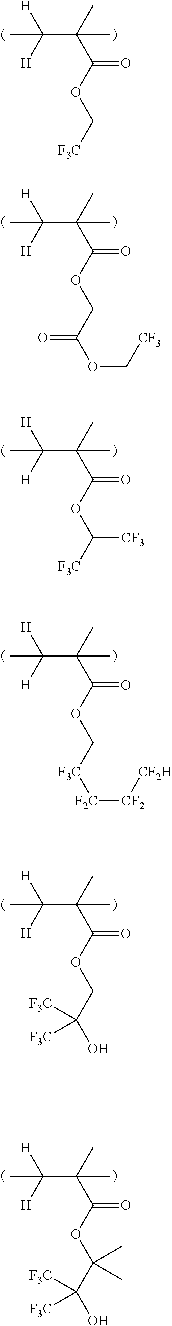

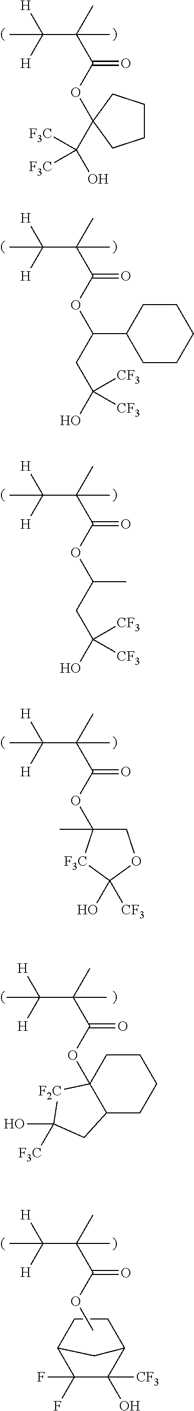

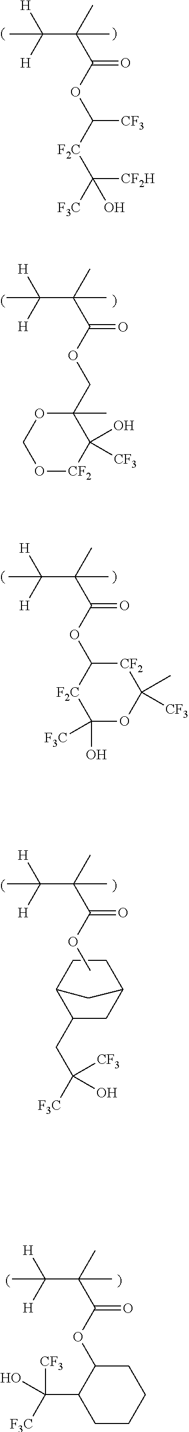

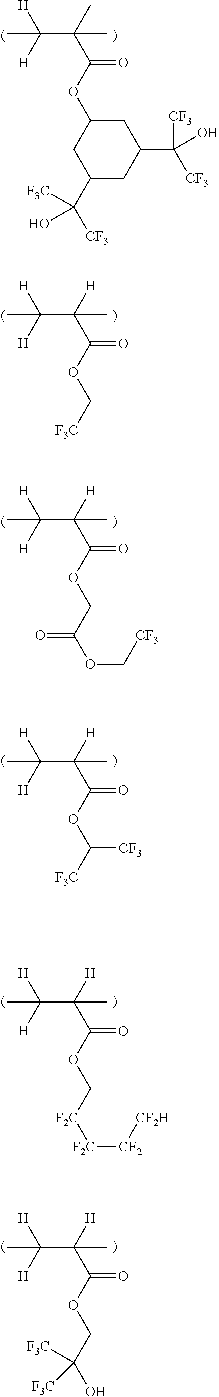 [SMILES: CCC(C)(C)C(=O)OC1CC(C(O)(C(F)(F)F)C(F)(F)F)CC(C(O)(C(F)(F)F)C(F)(F)F)C1 ; CCC(C)C(=O)OCC(F)(F)F ; CCC(C)C(=O)OCC(=O)OCC(F)(F)F ; CCC(C)C(=O)OC(C(F)(F)F)C(F)(F)F ; CCC(C)C(=O)OCC(F)(F)C(F)(F)C(F)(F)C(F)F ; CCC(C)C(=O)OCC(O)(C(F)(F)F)C(F)(F)F]

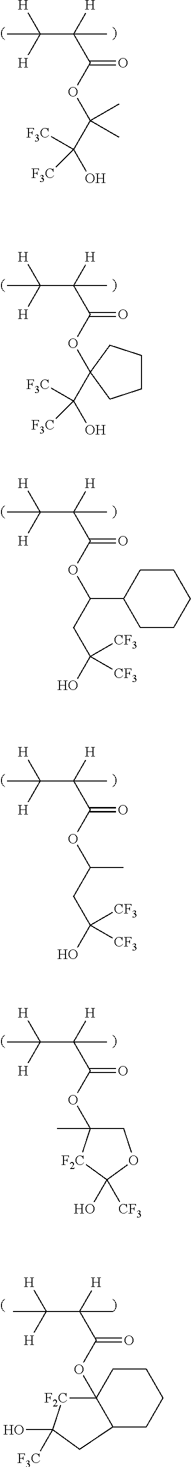

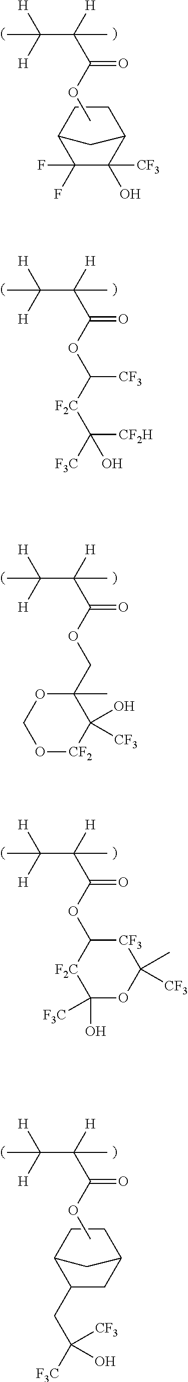

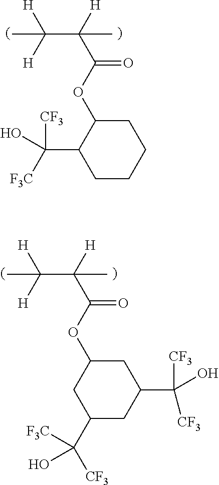 [SMILES: CCC(C)C(=O)OC1CCCCC1C(O)(C(F)(F)F)C(F)(F)F ; CCC(C)C(=O)OC1CC(C(O)(C(F)(F)F)C(F)(F)F)CC(C(O)(C(F)(F)F)C(F)(F)F)C1]

For the surfactant which is insoluble or substantially insoluble in water and soluble in alkaline developer, reference may be made to JP-A 2008-122932, 2010-134012, 2010-107695, 2009-276363, 2009-192784, 2009-191151, 2009-098638, 2010-250105, and 2011-042789.

The polymeric surfactant preferably has a Mw of 1,000 to 50,000, more preferably 2,000 to 20,000 as measured by GPC versus polystyrene standards. A surfactant with a Mw outside the range may be less effective for surface modification and cause development defects. The polymeric surfactant is preferably formulated in an amount of 0.001 to 20 parts, and more preferably 0.01 to 10 parts by weight per 100 parts by weight of the base resin. Reference should also be made to JP-A 2010-215608.

### Process

A further embodiment of the invention is a pattern forming process using the resist composition defined above. A pattern may be formed from the resist composition using any well-known lithography process. The preferred process includes at least the steps of forming a resist film on a substrate, exposing it to high-energy radiation, and developing it in a developer.

First the resist composition is applied onto a substrate for integrated circuitry fabrication (e.g., Si, SiO₂, SiN, SiON, TiN, WSi, BPSG, SOG, organic antireflective film, etc.) or a substrate for mask circuitry fabrication (e.g., Cr, CrO, CrON, MoSi, etc.) by a suitable coating technique such as spin coating. The coating is prebaked on a hot plate at a temperature of 60 to 150° C. for 1 to 10 minutes, preferably 80 to 140° C. for 1 to 5 minutes. The resulting resist film is generally 0.05 to 2.0 μm thick. Through a photomask having a desired pattern which is disposed over the resist film, the resist film is then exposed to high-energy radiation such as KrF excimer laser, ArF excimer laser or EUV in an exposure dose preferably in the range of 1 to 200 mJ/cm², more preferably 10 to 100 mJ/cm². Light exposure may be done by a conventional lithography process or in some cases, by an immersion lithography process of providing liquid impregnation, typically water, between the projection lens or mask and the resist film. In the case of immersion lithography, a protective film which is insoluble in water may be used. The resist film is then baked (PEB) on a hot plate at 60 to 150° C. for 1 to 5 minutes, and preferably at 80 to 140° C. for 1 to 3 minutes. Finally, development is carried out using as the developer an aqueous alkaline solution, such as a 0.1 to 5 wt %, preferably 2 to 3 wt %, aqueous solution of tetramethylammonium hydroxide (TMAH), this being done by a conventional method such as dip, puddle, or spray development for a period of 0.1 to 3 minutes, and preferably 0.5 to 2 minutes. While the exposed region of resist film is dissolved away, the desired positive pattern is formed on the substrate.

While the water-insoluble protective film which is used in the immersion lithography serves to prevent any components from being leached out of the resist film and to improve water slippage at the film surface, it is generally divided into two types. The first type is an organic solvent-strippable protective film which must be stripped, prior to alkaline development, with an organic solvent in which the resist film is not dissolvable. The second type is an alkali-soluble protective film which is soluble in an alkaline developer so that it can be removed simultaneously with the removal of solubilized regions of the resist film. The protective film of the second type is preferably of a material comprising a polymer having a 1,1,1,3,3,3-hexafluoro-2-propanol residue (which is insoluble in water and soluble in an alkaline developer) as a base in an alcohol solvent of at least 4 carbon atoms, an ether solvent of 8 to 12 carbon atoms or a mixture thereof. Alternatively, the aforementioned surfactant which is insoluble in water and soluble in an alkaline developer may be dissolved in an alcohol solvent of at least 4 carbon atoms, an ether solvent of 8 to 12 carbon atoms or a mixture thereof to form a material from which the protective film of the second type is formed.

Any desired step may be added to the pattern forming process. For example, after a photoresist film is formed, a step of rinsing with pure water (post-soaking) may be introduced to extract the acid generator or the like from the film surface or wash away particles. After exposure, a step of rinsing (post-soaking) may be introduced to remove any water remaining on the film after exposure.

The technique enabling the ArF lithography to survive to the 32-nm node is a double patterning process. The double patterning process includes a trench process of processing an underlay to a 1:3 trench pattern by a first step of exposure and etching, shifting the position, and forming a 1:3 trench pattern by a second step of exposure for forming a 1:1 pattern; and a line process of processing a first underlay to a 1:3 isolated left pattern by a first step of exposure and etching, shifting the position, processing a second underlay formed below the first underlay by a second step of exposure through the 1:3 isolated left pattern, for forming a half-pitch 1:1 pattern.

In the pattern forming process, an alkaline aqueous solution, typically an aqueous solution of 0.1 to 5 wt %, more typically 2 to 3 wt % of tetramethylammonium hydroxide (TMAH) is often used as the developer. The negative tone development technique wherein the unexposed region of resist film is developed and dissolved in an organic solvent is also applicable.

In the organic solvent development, the organic solvent used as the developer is preferably selected from 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, isopentyl acetate, butenyl acetate, phenyl acetate, propyl formate, butyl formate, isobutyl formate, pentyl formate, isopentyl formate, methyl valerate, methyl pentenoate, methyl crotonate, ethyl crotonate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, benzyl acetate, methyl phenylacetate, benzyl formate, phenylethyl formate, methyl 3-phenylpropionate, benzyl propionate, ethyl phenylacetate, and 2-phenylethyl acetate. These organic solvents may be used alone or in admixture of two or more.

### EXAMPLE

Examples and Comparative Examples are given below by way of illustration and not by way of limitation. All parts are by weight (pbw).

### Synthesis Example 1

### Synthesis of benzyltrimethylammonium 2-hydroxy-1,1,3,3,3-pentafluoropropane-1-sulfonate (Additive-1)

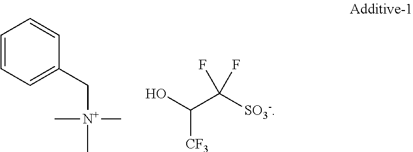

An aqueous solution of sodium 2-hydroxy-1,1,3,3,3-pentafluoropropane-1-sulfonate was synthesized according to the method of JP-A 2010-215608. To 1,200 g of the aqueous solution (corresponding to 1 mol of sodium 2-hydroxy-1,1,3,3,3-pentafluoropropane-1-sulfonate) were added 223 g of benzyltrimethylammonium chloride and 2,000 g of methylene chloride. The solution was stirred for 10 minutes, after which the water layer was removed and the organic solvent layer was concentrated under reduced pressure. Diisopropyl ether was added to the concentrate for crystallization. The solid precipitate was recovered and dried in vacuum, obtaining 354 g of the target compound, benzyltrimethylammonium 2-hydroxy-1,1,3,3,3-pentafluoropropane-1-sulfonate (Additive-1), as white solid (yield 86%).

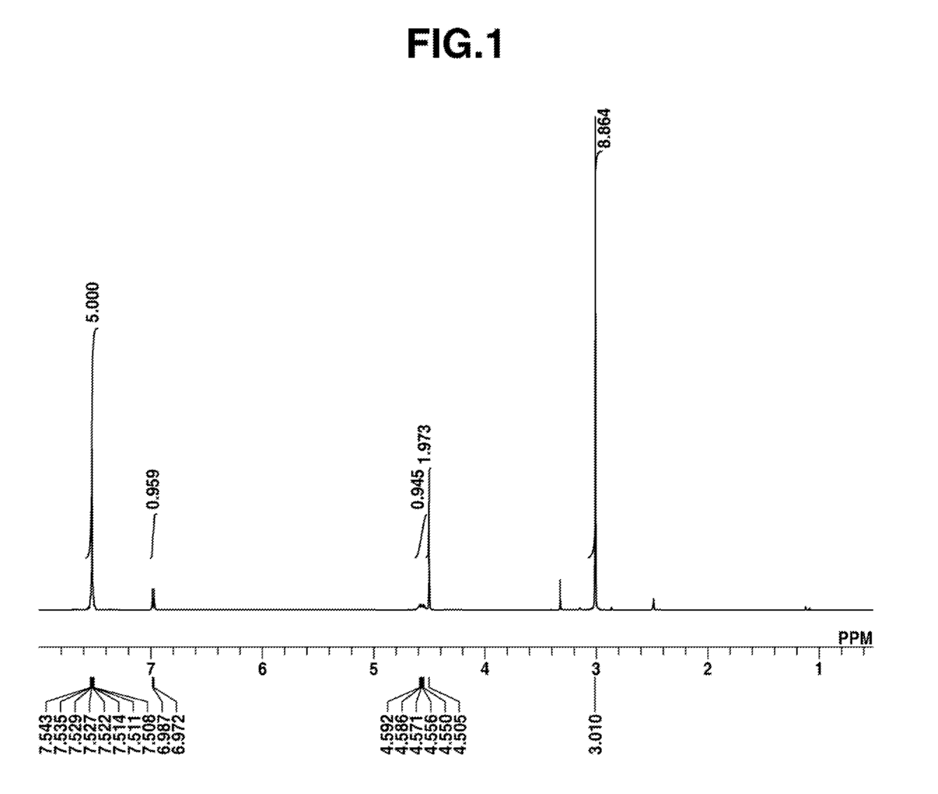

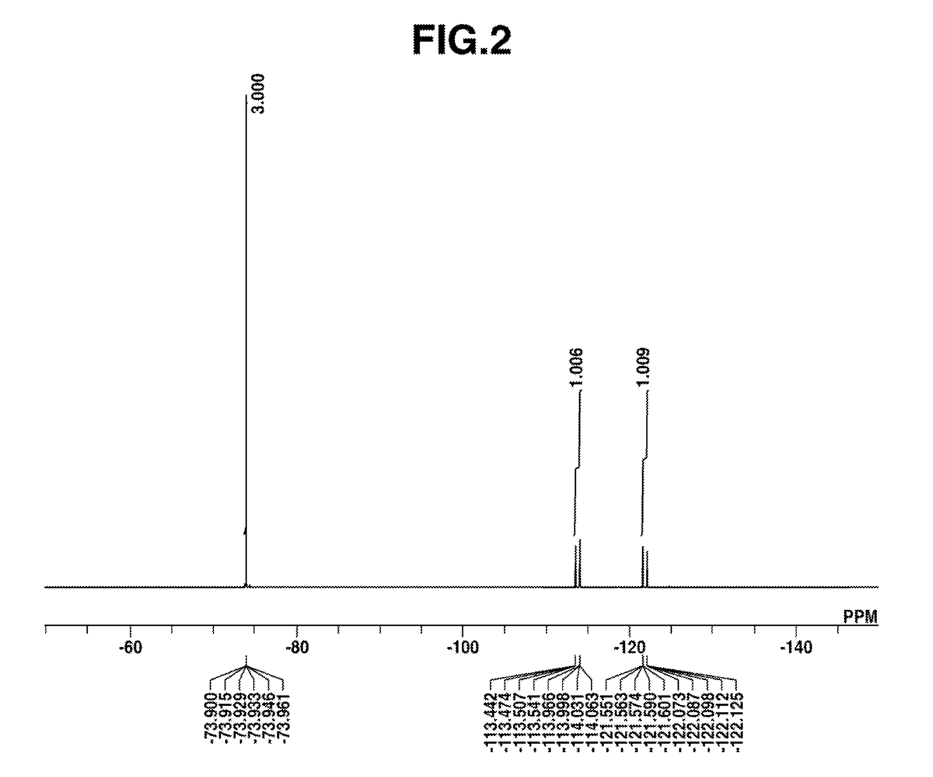

The target compound was analyzed by spectroscopy. The data of infrared absorption (IR) and time-of-flight mass spectrometry (TOFMS) are shown below. The NMR spectra, ¹H- and ¹⁹F-NMR in DMSO-d₆ are shown in FIGS. 1 and 2. On ¹H-NMR analysis, water in DMSO-d₆ was observed.

IR (D-ATR): 3287, 1490, 1484, 1457, 1371, 1262, 1232, 1210, 1160, 1133, 1110, 1071, 989, 975, 892, 837, 818, 786, 734, 705, 643, 615, 556 cm⁻¹

TOFMS (MALDI)

Positive M⁺ 150 (corresponding to C₁₀H₁₆N⁺)

Negative M⁻ 229 (corresponding to CF₃CH(OH)CF₂SO₃⁻)

### Synthesis Example 1-2

### Synthesis of benzyltrimethylammonium 2-(adamantane-1-carbonyloxy)-1,1,3,3,3-pentafluoropropane-1-sulfonate (Additive-2)

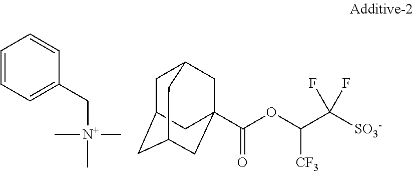

In toluene solvent, 1-adamantanecarboxylic acid was reacted with oxazolyl chloride to form a corresponding carboxylic acid chloride, to which methylene chloride was added to form a 25 wt % solution (corresponding to 0.4 mol). Separately, another solution was prepared by mixing 151 g of Additive-1 (in Synthesis Example 1-1), 45 g of triethylamine, and 9 g of 4-dimethylaminopyridine in 750 g of methylene chloride. Under ice cooling, the carboxylic acid chloride/methylene chloride solution was added dropwise to the other solution. After the completion of dropwise addition, the solution was aged at room temperature for 10 hours. Thereafter, dilute hydrochloric acid was added to the reaction solution to quench the reaction. An organic layer was taken out, washed with water, and concentrated under reduced pressure. Diisopropyl ether, 20 g, was added to the concentrate for crystallization. The crystal was collected by filtration and dried in vacuum, obtaining 193 g of the target compound, benzyltrimethylammonium 2-(adamantane-1-carbonyloxy)-1,1,3,3,3-pentafluoropropane-1-sulfonate (Additive-2), as white crystal (yield 80%).

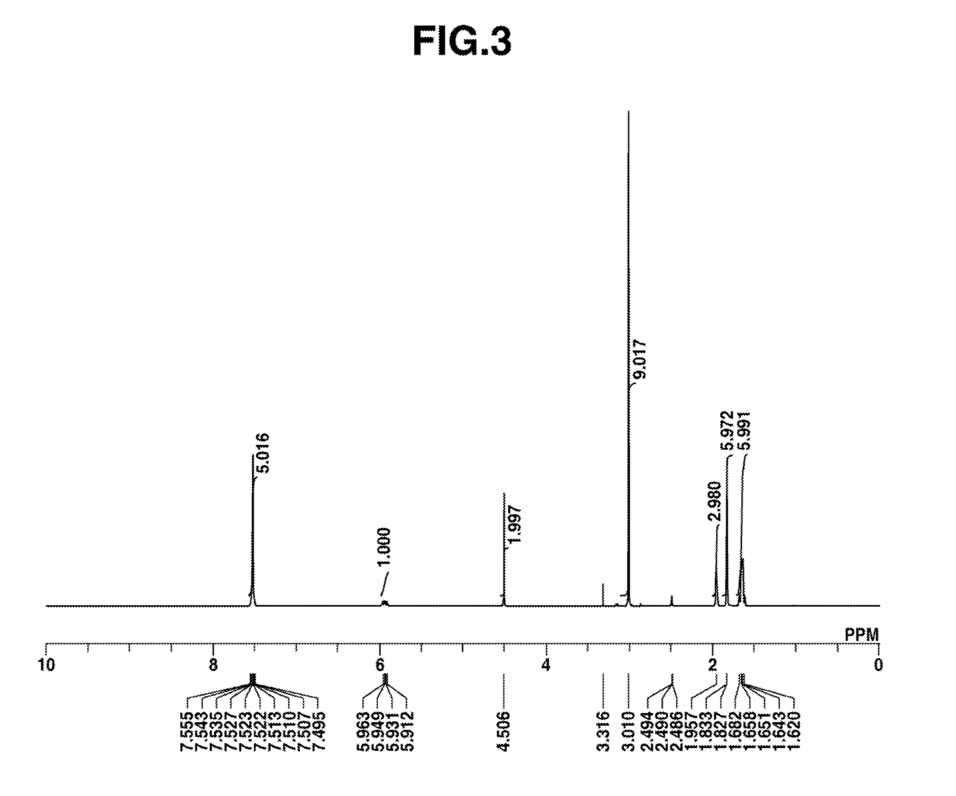

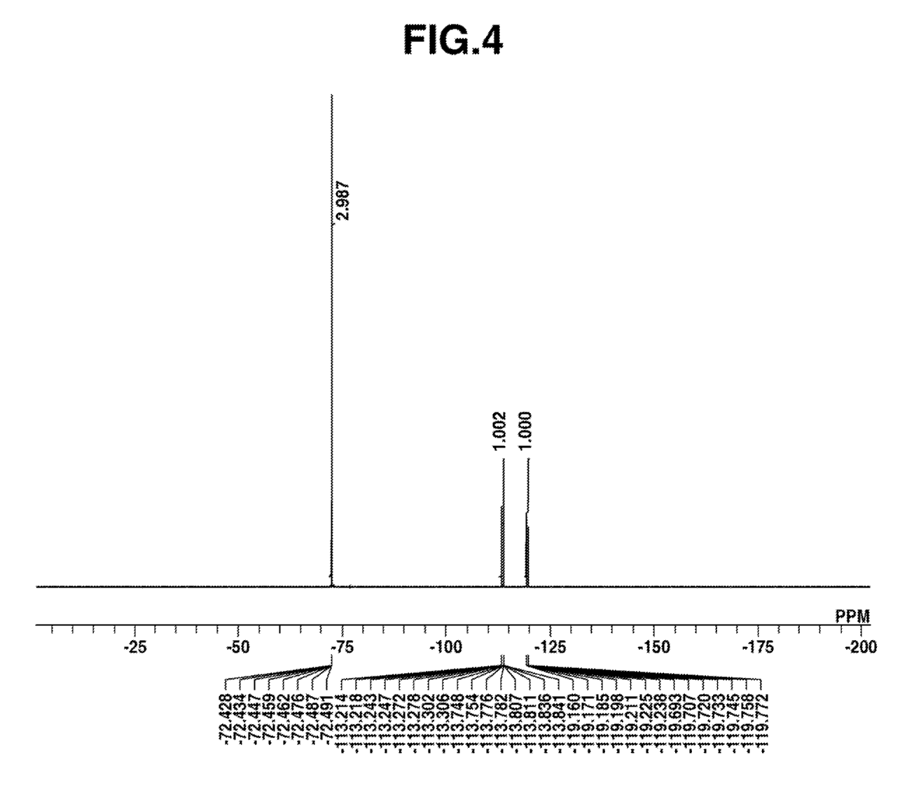

The target compound was analyzed by spectroscopy. The data of IR and TOFMS are shown below. The NMR spectra, ¹H- and ¹⁹F-NMR in DMSO-d₆ are shown in FIGS. 3 and 4. On ¹H-NMR analysis, water in DMSO-d₆ was observed.

IR (D-ATR): 2909, 2856, 1747, 1264, 1249, 1215, 1182, 1165, 1102, 1084, 992, 917, 888, 839, 780, 724, 703, 640 cm⁻¹

TOFMS (MALDI)

Positive M⁺ 150 (corresponding to C₁₀H₁₆N⁺)

Negative M⁻ 391 (corresponding to CF₃CH(OCOC₁₀H₁₅)CF₂SO₃⁻)

### Synthesis Example 1-3

### Synthesis of benzyltrimethylammonium 2-(24-nor-5β-cholane-3,7,12-trion-23-ylcarbonyloxy)-1,1,3,3,3-pentafluoropropane-1-sulfonate (Additive-3)

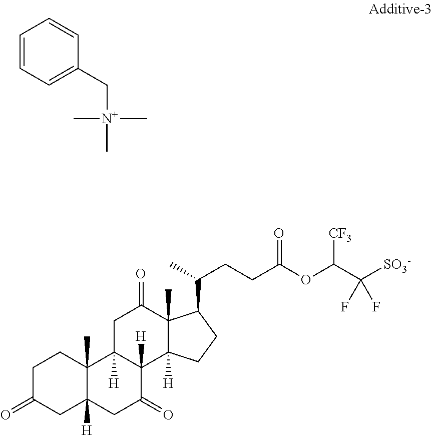

While a mixture of 3.8 g of Additive-1 (in Synthesis Example 1-1), 4.2 g of dehydrocholic acid chloride, and 20 g of dichloromethane was ice cooled, a mixture of 1.0 g of triethylamine, 0.2 g of 4-dimethylaminopyridine and 5 g of dichloromethane was added dropwise thereto. After the completion of dropwise addition, the solution was aged at room temperature for 10 hours. Dilute hydrochloric acid was added to the reaction solution to quench the reaction. An organic layer was taken out, washed with water, combined with methyl isobutyl ketone, and concentrated under reduced pressure. Diisopropyl ether, 1,500 g, was added to the concentrate for crystallization. The crystal was collected by filtration and dried in vacuum, obtaining 6.1 g of the target compound, benzyltrimethylammonium 2-(24-nor-53-cholane-3,7,12-trion-23-ylcarbonyloxy)-1,1,3,3,3-pentafluoropropane-1-sulfonate (Additive-3), as white crystal (yield 80%).

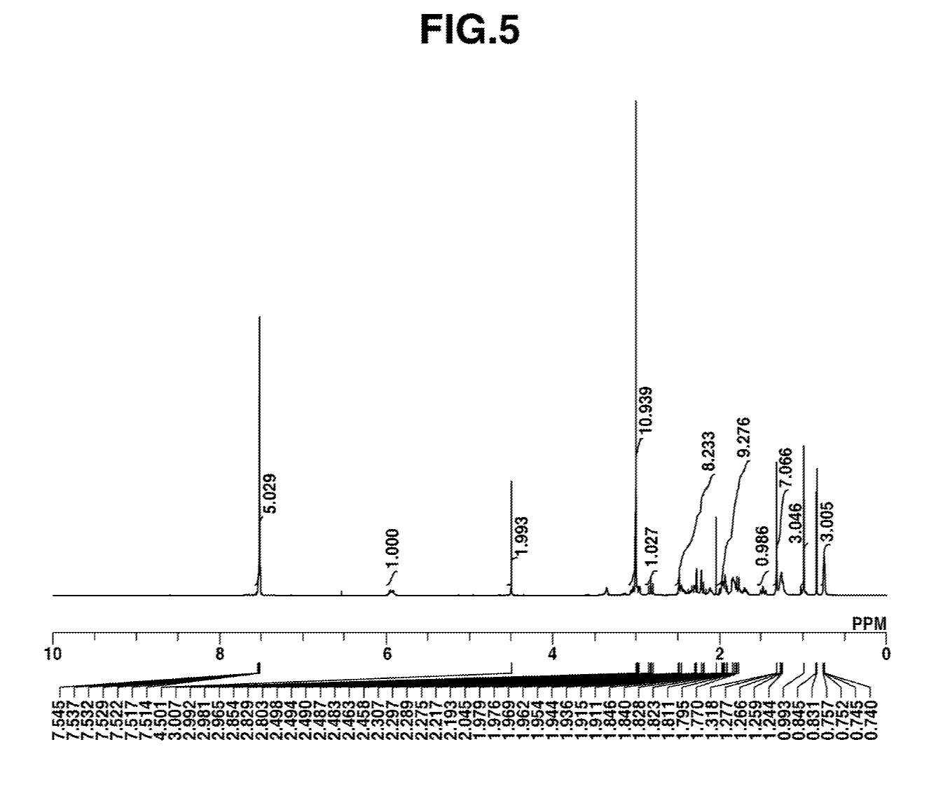

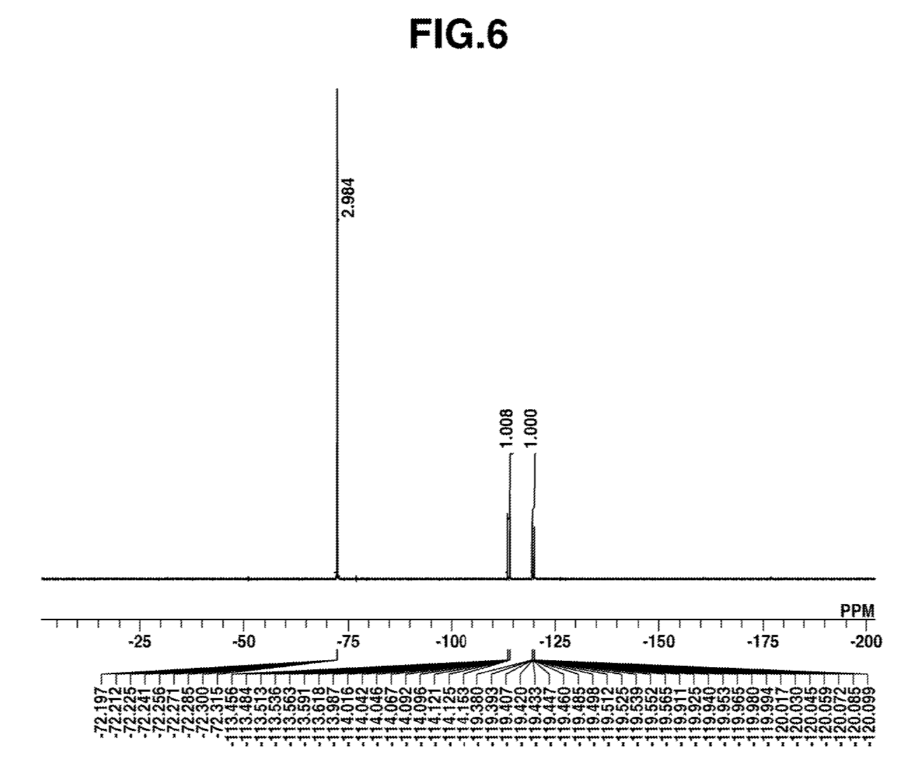

The target compound was analyzed by spectroscopy. The data of IR and TOFMS are shown below. The NMR spectra, ¹H- and ¹⁹F-NMR in DMSO-d₆ are shown in FIGS. 5 and 6. On ¹H-NMR analysis, trace amounts of residual solvents (diisopropyl ether and methyl isobutyl ketone) and water in DMSO-d₆ were observed.

IR (D-ATR): 2968, 2876, 1768, 1706, 1491, 1478, 1459, 1380, 1245, 1218, 1184, 1169, 1120, 1073, 992, 921, 892, 727, 703, 643, 554 cm⁻¹

TOFMS (MALDI)

Positive M⁺ 150 (corresponding to C₁₀H₁₆N⁺)

Negative M⁻ 613 (corresponding to CF₃CH(OCO—C₂₃H₃₃O₃)CF₂SO₃⁻)

### Synthesis Example 1-4

### Synthesis of tetrabutylammonium 2-(24-nor-5β-cholane-3,7,12-trion-23-ylcarbonyloxy)-1, 1,3,3,3-pentafluoropropane-1-sulfonate (Additive-4)

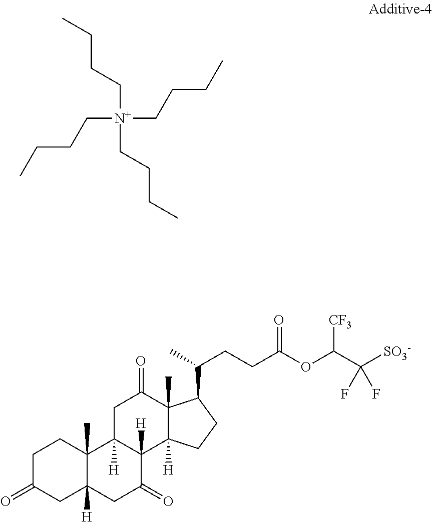

A solution was prepared by mixing 15 g of Additive-3 (in Synthesis Example 1-3), 8.2 g of tetrabutylammonium hydrogensulfate, 80 g of dichloromethane, and 40 g of water, and aged at room temperature for 30 minutes. Thereafter, an organic layer was taken out, washed with water, combined with methyl isobutyl ketone, and concentrated under reduced pressure. The concentrate was washed with diisopropyl ether, obtaining 16.8 g of the target compound, tetrabutylammonium 2-(24-nor-5-cholane-3,7,12-trion-23-ylcarbonyloxy)-1,1,3,3,3-pentafluoropropane-1-sulfonate (Additive-4), as oily matter (yield 98%).

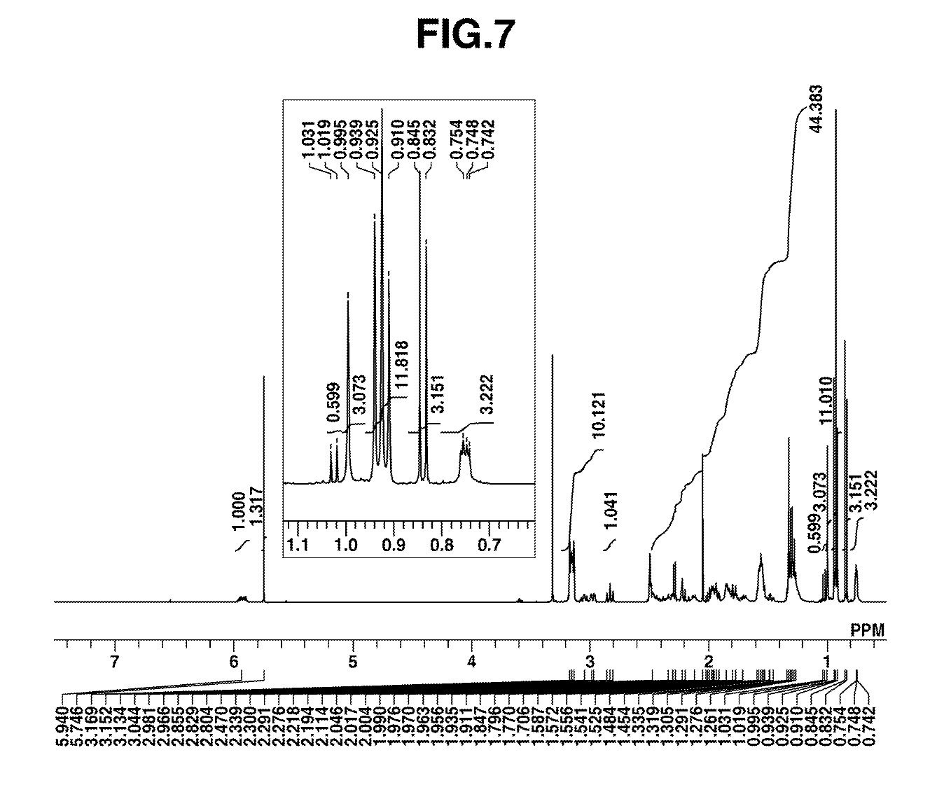

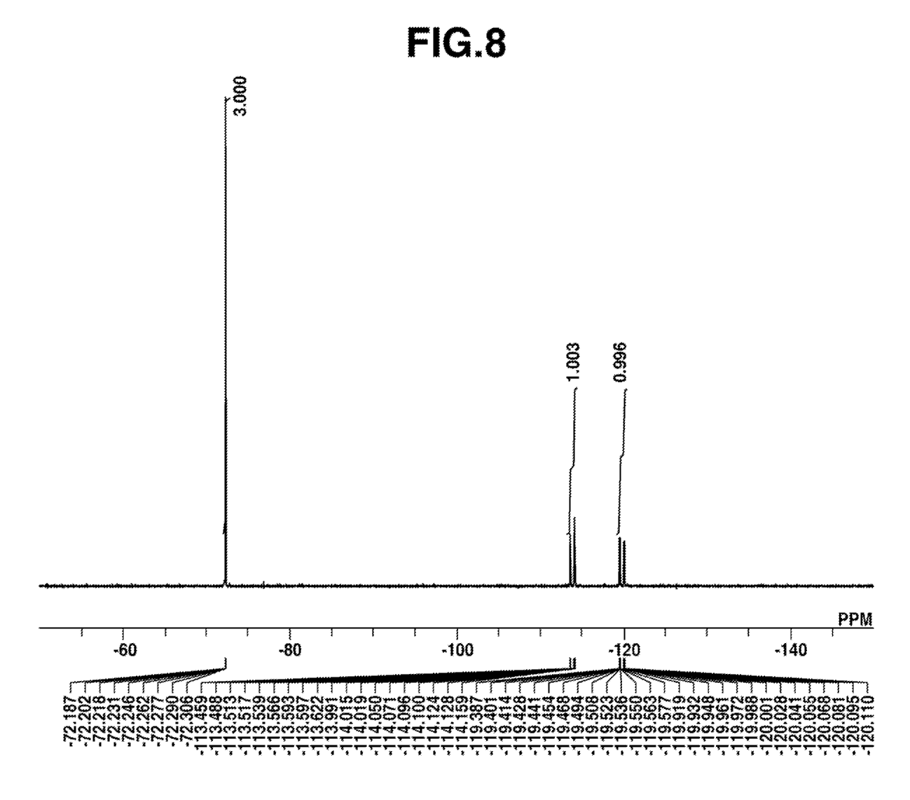

The target compound was analyzed by spectroscopy. The data of IR and TOFMS are shown below. The NMR spectra, ¹H- and ¹⁹F-NMR in DMSO-d₆ are shown in FIGS. 7 and 8. On 1H-NMR analysis, trace amounts of residual solvents (diisopropyl ether and methyl isobutyl ketone) and water in DMSO-d₆ were observed.

IR (D-ATR): 2963, 2876, 1769, 1711, 1467, 1381, 1250, 1215, 1183, 1168, 1119, 1070, 992, 735, 642 cm⁻¹

TOFMS (MALDI)

Positive M⁺ 242 (corresponding to C₁₆H₃₆N⁺)

Negative M⁻ 613 (corresponding to CF₃CH(OCO—C₂₃H₃₃O₃)CF₂SO₃⁻)

### Synthesis Example 2-1

### Synthesis of Polymer P-1

In a flask under nitrogen atmosphere, 32.9 g of triphenylsulfonium 2-methacryloyloxy-1,1,3,3,3-pentafluoropropane-1-sulfonate, 24.1 g of 3-ethyl-3-exo-tetracyclo-[4.4.0.1^{2,5}.1^{7,10}]dodecanyl methacrylate, 10.4 g of 4-hydroxyphenyl methacrylate, 19.7 g of 4,8-dioxatricyclo-[4.2.1.0^{3,7}]nonan-5-on-2-yl methacrylate, 3.4 g of dimethyl 2,2′-azobis(isobutyrate), 0.69 g of 2-mercaptoethanol, and 175 g of methyl ethyl ketone (MEK) were mixed to form a monomer solution. Another flask under nitrogen atmosphere was charged with 58 g of MEK, which was heated at 80° C. with stirring. With stirring, the monomer solution was added dropwise to the other flask over 4 hours. After the completion of dropwise addition, the polymerization solution was continuously stirred for 2 hours while maintaining the temperature of 80° C. The polymerization solution was cooled to room temperature, whereupon it was added dropwise to a mixture of 100 g MEK and 900 g hexane. The precipitate was collected by filtration, washed twice with 600 g of hexane, and vacuum dried at 50° C. for 20 hours, obtaining a polymer (P-1) in white powder solid form. Amount 77.5 g, yield 89%. The polymer (P-1) has the structure shown below.

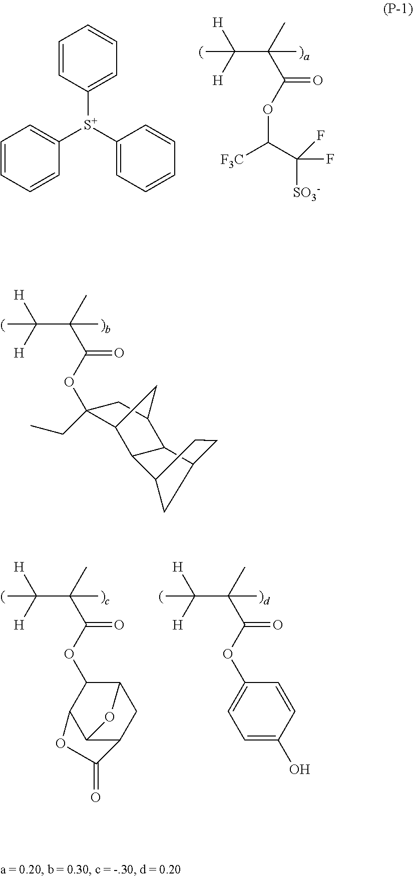

### Synthesis Examples 2-2 to 2-15

### Synthesis of Polymers P-2 to P-15

Polymers (or resins) were synthesized by the same procedure as in Synthesis Example 2-1 aside from changing the type and amount of monomers. Table 1 shows the proportion (in molar ratio) of units incorporated in these polymers, and Tables 2 to 4 show the structure of recurring units.

TABLE 1

| | Unit 1 | Unit 2 | Unit 3 | Unit 4 | Unit 5 |
|---|---|---|---|---|---|
| Resin | (molar ratio) | (molar ratio) | (molar ratio) | (molar ratio) | (molar ratio) |
| P-1 | PAG Monomer-1 (0.20) | A-1 (0.30) | B-1 (0.20) | B-5 (0.30) | — |
| P-2 | PAG Monomer-2 (0.20) | A-1 (0.30) | B-1 (0.20) | B-5 (0.30) | — |
| P-3 | PAG Monomer-3 (0.20) | A-1 (0.30) | B-1 (0.20) | B-5 (0.30) | — |
| P-4 | PAG Monomer-4 (0.20) | A-1 (0.30) | B-1 (0.20) | B-5 (0.30) | — |
| P-5 | PAG Monomer-5 (0.20) | A-1 (0.30) | B-1 (0.20) | B-5 (0.30) | — |
| P-6 | PAG Monomer-6 (0.20) | A-1 (0.30) | B-1 (0.20) | B-5 (0.30) | — |
| P-7 | PAG Monomer-2 (0.20) | A-2 (0.30) | B-1 (0.20) | B-3 (0.30) | — |
| P-8 | PAG Monomer-2 (0.20) | A-1 (0.20) | A-4 (0.20) | B-1 (0.20) | B-5 (0.20) |
| P-9 | PAG Monomer-2 (0.20) | A-1 (0.20) | A-5 (0.20) | B-1 (0.20) | B-5 (0.20) |
| P-10 | PAG Monomer-2 (0.20) | A-1 (0.20) | A-6 (0.20) | B-1 (0.20) | B-5 (0.20) |
| P-11 | PAG Monomer-2 (0.20) | A-1 (0.20) | A-4 (0.20) | B-5 (0.20) | B-6 (0.20) |
| P-12 | A-3 (0.40) | B-2 (0.10) | B-5 (0.50) | — | — |
| P-13 | A-2 (0.40) | B-2 (0.10) | B-3 (0.50) | — | — |
| P-14 | A-1 (0.40) | B-2 (0.10) | B-4 (0.50) | — | — |
| P-15 | A-1 (0.20) | A-2 (0.30) | B-2 (0.10) | B-5 (0.40) | — |

TABLE 2

| | |
|---|---|
| 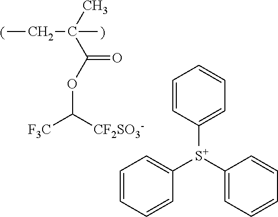 | PAG Monomer-1 |
| 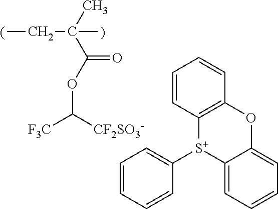 | PAG Monomer-2 |
| 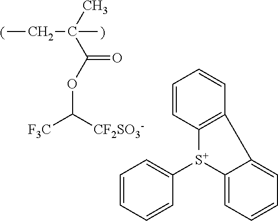 | PAG Monomer-3 |
| 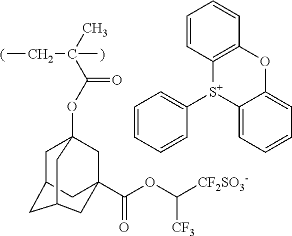 | PAG Monomer-4 |
| 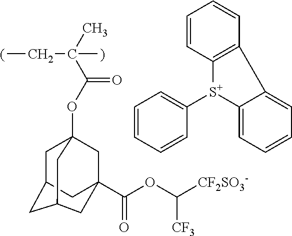 | PAG Monomer-5 |
| 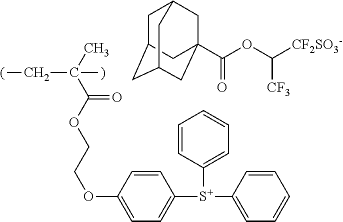 | PAG Monomer-6 |

TABLE 3

| | |
|---|---|
| 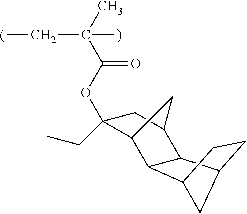 | A-1 |
| 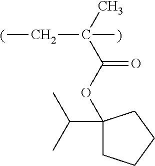 | A-2 |
| 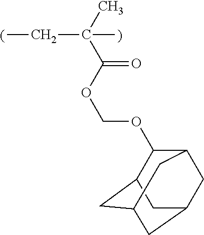 | A-3 |
| 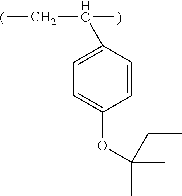 | A-4 |
| 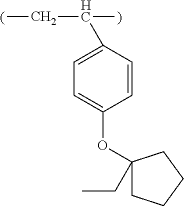 | A-5 |
| 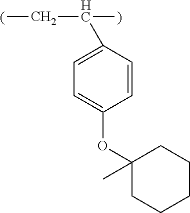 | A-6 |

TABLE 4

| | |
|---|---|
| 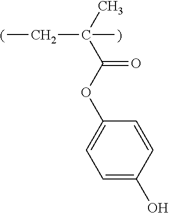 | B-1 |
| 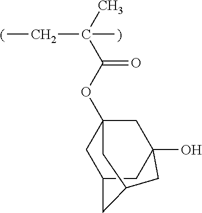 | B-2 |
| 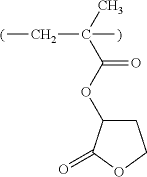 | B-3 |
| 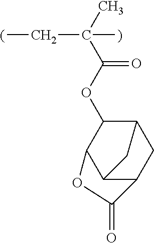 | B-4 |
| 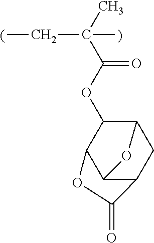 | B-5 |
| 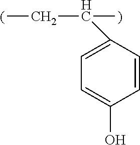 | B-6 |

### Examples 1-1 to 1-15 and Comparative Examples 1-1 to 1-19

### Preparation of Resist Composition

A resist composition in solution form was prepared by dissolving each ammonium salt (Additive-1 to 4 in Synthesis Example 1), each polymer (Polymers P-1 to P-15 in Synthesis Example 2), optionally a photoacid generator (PAG-A), quencher (Q-1), and alkali-soluble surfactant (F-1) in an organic solvent containing 0.01 wt % of surfactant A, and filtering through a Teflon® filter with a pore size of 0.2 μm. For comparison sake, a resist solution was prepared by blending an ammonium salt (Additive-A) outside the scope of the inventive ammonium salt. Table 5 shows the formulation of the resulting resist solutions.

The photoacid generator (PAG-A), quencher (Q-1), solvent, alkali-soluble surfactant (F-1), and surfactant A used herein are identified below.
FAG-A: triphenylsulfonium 2-(adamantane-1-carbonyloxy)-1,1,3,3,3-pentafluoropropane-1-sulfonate (described in JP-A 2007-145797)
Q-1: 2-(4-morpholinyl)ethyl laurate
PGMEA: propylene glycol monomethyl ether acetate
GBL: γ-butyrolactone
CyHO: cyclohexanone
Additive-A: tetrabutylammonium 10-camphorsulfonate

### Surfactant (F-1): poly(2,2,3,3,4,4,4-heptafluoro-1-isobutyl-1-butyl methacrylate/9-(2,2,2-trifluoro-1-trifluoroethyloxycarbonyl)-4-oxatriyclo-[4.2.1.0^{3,7}]nonan-5-on-2-yl methacrylate)

Mw=7,700

Mw/Mn=1.82

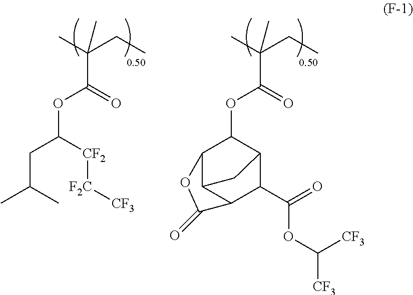

### Surfactant A: 3-methyl-3-(2,2,2-trifluoroethoxymethyl)-oxetane/tetrahydrofuran/2,2-dimethyl-1,3-propanediol copolymer (Omnova Solutions, Inc.)

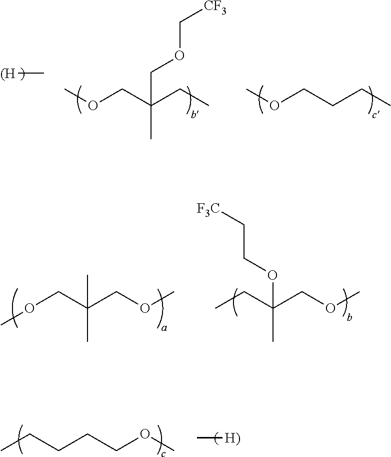

a:(b+b′):(c+c′)=1:4-7:0.01-1 (molar ratio)

Mw=1,500

TABLE 5

| | | | Resin | Additive | PAG | Quencher | Surfactant | Solvent 1 | Solvent 2 |
|---|---|---|---|---|---|---|---|---|---|
| | | Resist | (pbw) | (pbw) | (pbw) | (pbw) | (pbw) | (pbw) | (pbw) |
| Example | 1-1 | R-1 | P-1 | Additive-1 | — | Q-1 | — | PGMEA | CyHO |
| | | | (80) | (4.4) | | (0.7) | | (576) | (1,728) |
| | 1-2 | R-2 | P-2 | Additive-2 | — | Q-1 | — | PGMEA | CyHO |
| | | | (80) | (6.3) | | (0.7) | | (576) | (1,728) |
| | 1-3 | R-3 | P-3 | Additive-3 | — | Q-1 | — | PGMEA | CyHO |
| | | | (80) | (8.9) | | (0.7) | | (576) | (1,728) |
| | 1-4 | R-4 | P-4 | Additive-4 | — | Q-1 | — | PGMEA | CyHO |
| | | | (80) | (9.9) | | (0.7) | | (576) | (1,728) |
| | 1-5 | R-5 | P-5 | Additive-2 | — | Q-1 | — | PGMEA | CyHO |
| | | | (80) | (6.3) | | (0.7) | | (576) | (1,728) |
| | 1-6 | R-6 | P-6 | Additive-2 | — | Q-1 | — | PGMEA | GBL |
| | | | (80) | (6.3) | | (0.7) | | (1,728) | (192) |
| | 1-7 | R-7 | P-7 | Additive-2 | — | Q-1 | — | PGMEA | GBL |
| | | | (80) | (6.3) | | (0.7) | | (1,728) | (192) |
| | 1-8 | R-8 | P-8 | Additive-2 | — | Q-1 | — | PGMEA | GBL |
| | | | (80) | (6.3) | | (0.7) | | (1,728) | (192) |
| | 1-9 | R-9 | P-9 | Additive-2 | — | Q-1 | — | PGMEA | CyHO |
| | | | (80) | (6.3) | | (0.7) | | (576) | (1,728) |
| | 1-10 | R-10 | P-10 | Additive-2 | — | Q-1 | — | PGMEA | GBL |
| | | | (80) | (6.3) | | (0.7) | | (1,728) | (192) |
| | 1-11 | R-11 | P-11 | Additive-2 | — | Q-1 | — | PGMEA | CyHO |
| | | | (80) | (6.3) | | (0.7) | | (576) | (1,728) |
| | 1-12 | R-12 | P-12 | Aaditive-4 | PAG-A | Q-1 | F-1 | PGMEA | GBL |
| | | | (80) | (9.9) | (7.6) | (1.5) | (5.0) | (1,728) | (192) |
| | 1-13 | R-13 | P-13 | Additive-4 | PAG-A | Q-1 | F-1 | PGMEA | GBL |
| | | | (80) | (9.9) | (7.6) | (1.5) | (5.0) | (1,728) | (192) |
| | 1-14 | R-14 | P-14 | Additive-4 | PAG-A | Q-1 | F-1 | PGMEA | GBL |
| | | | (80) | (9.9) | (7.6) | (1.5) | (5.0) | (1,728) | (192) |
| | 1-15 | R-15 | P-15 | Additive-4 | PAG-A | Q-1 | F-1 | PGMEA | GBL |
| | | | (80) | (9.9) | (7.6) | (1.5) | (5.0) | (1,728) | (192) |
| Comparative | 1-1 | R-16 | P-1 | — | — | Q-1 | — | PGMEA | CyHO |
| Example | | | (80) | | | (0.7) | | (576) | (1,728) |
| | 1-2 | R-17 | P-2 | — | — | Q-1 | — | PGMEA | CyHO |
| | | | (80) | | | (0.7) | | (576) | (1,728) |
| | 1-3 | R-18 | P-3 | — | — | Q-1 | — | PGMEA | GBL |
| | | | (80) | | | (0.7) | | (1,728) | (192) |
| | 1-4 | R-19 | P-4 | — | — | Q-1 | — | PGMEA | CyHO |
| | | | (80) | | | (0.7) | | (576) | (1,728) |
| | 1-5 | R-20 | P-5 | — | — | Q-1 | — | PGMEA | CyHO |
| | | | (80) | | | (0.7) | | (576) | (1,728) |
| | 1-6 | R-21 | P-6 | — | — | Q-1 | — | PGMEA | CyHO |
| | | | (80) | | | (0.7) | | (576) | (1,728) |
| | 1-7 | R-22 | P-7 | — | — | Q-1 | — | PGMEA | CyHO |
| | | | (80) | | | (0.7) | | (576) | (1,728) |
| | 1-8 | R-23 | P-8 | — | — | Q-1 | — | PGMEA | CyHO |
| | | | (80) | | | (0.7) | | (576) | (1,728) |
| | 1-9 | R-24 | P-9 | — | — | Q-1 | — | PGMEA | CyHO |
| | | | (80) | | | (0.7) | | (576) | (1,728) |
| | 1-10 | R-25 | P-10 | — | — | Q-1 | — | PGMEA | CyHO |
| | | | (80) | | | (0.7) | | (576) | (1,728) |
| | 1-11 | R-26 | P-11 | — | — | Q-1 | — | PGMEA | CyHO |
| | | | (80) | | | (0.7) | | (576) | (1,728) |
| | 1-12 | R-27 | P-2 | — | PAG-A | Q-1 | — | PGMEA | CyHO |
| | | | (80) | | (7.6) | (0.7) | | (576) | (1,728) |
| | 1-13 | R-28 | P-2 | Additive-A | — | Q-1 | — | PGMEA | CyHO |
| | | | (80) | (5.5) | | (0.7) | | (576) | (1,728) |
| | 1-14 | R-29 | P-12 | — | PAG-A | Q-1 | F-1 | PGMEA | GBL |
| | | | (80) | | (7.6) | (1.5) | (5.0) | (1,728) | (192) |
| | 1-15 | R-30 | P-13 | — | PAG-A | Q-1 | F-1 | PGMEA | GBL |
| | | | (80) | | (7.6) | (1.5) | (5.0) | (1,728) | (192) |
| | 1-16 | R-31 | P-14 | — | PAG-A | Q-1 | F-1 | PGMEA | GBL |
| | | | (80) | | (7.6) | (1.5) | (5.0) | (1,728) | (192) |
| | 1-17 | R-32 | P-15 | — | PAG-A | Q-1 | F-1 | PGMEA | GBL |
| | | | (80) | | (7.6) | (1.5) | (5.0) | (1,728) | (192) |
| | 1-18 | R-33 | P-15 | — | PAG-A | Q-1 | F-1 | PGMEA | GBL |
| | | | (80) | | (15.2) | (1.5) | (5.0) | (1,728) | (192) |
| | 1-19 | R-34 | P-15 | Additive-A | PAG-A | Q-1 | F-1 | PGMEA | GBL |
| | | | (80) | (5.5) | (7.6) | (1.5) | (5.0) | (1,728) | (192) |

### Evaluation Examples 1-1 to 1-11 and Evaluation Comparative Examples 1-1 to 1-13

### Resist Test 1 (EUV Lithography Test)

Each of the resist compositions (R-1 to R-11 in Table 5) or comparative resist compositions (R-16 to R-28 in Table 5) was spin coated on a silicon substrate (diameter 100 mm=4 inches, vapor primed with hexamethyldisilazane (HMDS)) and prebaked on a hot plate at 105° C. for 60 seconds to form a resist film of 50 nm thick. EUV exposure was performed by dipole illumination at NA 0.3. Immediately after the exposure, the resist film was baked (PEB) on a hot plate for 60 seconds and puddle developed in a 2.38 wt % TMAH aqueous solution for 30 seconds to form a positive pattern.

Sensitivity is defined as the exposure dose (mJ/cm²) that provides a 1:1 resolution of a 35-nm line-and-space pattern. Resolution is a minimum size that can be resolved at that dose. A size variation (3σ) of the 35-nm L/S pattern is determined and reported as LER (nm). The results (sensitivity, resolution and LER) of the resist compositions by the EUV lithography test are shown in Table 6.

TABLE 6

| | | Sensitivity | Resolution | LER |
|---|---|---|---|---|
| | Resist | (mJ/cm²) | (nm) | (nm) |
| Evaluation Example 1-1 | R-1 | 24 | 28 | 3.4 |
| Evaluation Example 1-2 | R-2 | 23 | 26 | 3.2 |
| Evaluation Example 1-3 | R-3 | 23 | 25 | 3.2 |
| Evaluation Example 1-4 | R-4 | 22 | 24 | 2.8 |
| Evaluation Example 1-5 | R-5 | 21 | 23 | 2.7 |
| Evaluation Example 1-6 | R-6 | 22 | 30 | 3.6 |
| Evaluation Example 1-7 | R-7 | 24 | 32 | 3.2 |
| Evaluation Example 1-8 | R-8 | 20 | 26 | 3.0 |
| Evaluation Example 1-9 | R-9 | 18 | 24 | 3.3 |
| Evaluation Example 1-10 | R-10 | 19 | 22 | 3.2 |
| Evaluation Example 1-11 | R-11 | 18 | 25 | 3.1 |
| Evaluation Comparative | R-16 | 44 | 48 | 3.7 |
| Example 1-1 | | | | |
| Evaluation Comparative | R-17 | 42 | 48 | 3.5 |
| Example 1-2 | | | | |
| Evaluation Comparative | R-18 | 42 | 46 | 3.5 |
| Example 1-3 | | | | |
| Evaluation Comparative | R-19 | 45 | 45 | 3.2 |
| Example 1-4 | | | | |
| Evaluation Comparative | R-20 | 46 | 44 | 3.1 |
| Example 1-5 | | | | |
| Evaluation Comparative | R-21 | 44 | 50 | 4.0 |
| Example 1-6 | | | | |
| Evaluation Comparative | R-22 | 46 | 53 | 3.7 |
| Example 1-7 | | | | |
| Evaluation Comparative | R-23 | 39 | 43 | 3.5 |
| Example 1-8 | | | | |
| Evaluation Comparative | R-24 | 37 | 42 | 3.8 |
| Example 1-9 | | | | |
| Evaluation Comparative | E-25 | 38 | 42 | 3.6 |
| Example 1-10 | | | | |
| Evaluation Comparative | R-26 | 39 | 44 | 3.6 |
| Example 1-11 | | | | |
| Evaluation Comparative | R-27 | 24 | 50 | 4.2 |
| Example 1-12 | | | | |
| Evaluation Comparative | R-28 | 52 | 49 | 3.4 |
| Example 1-13 | | | | |

It is evident from Table 6 that the resist compositions containing an ammonium salt and a polymer within the scope of the invention exhibit a high resolution and low LER, when processed by the EUV lithography.

### Evaluation Examples 2-1 to 2-4 and Evaluation Comparative Examples 2-1 to 2-6

### Resist Test 2 (ArF Lithography Test)

On a silicon wafer, a spin-on carbon film ODL-50 (carbon content 80 wt %, Shin-Etsu Chemical Co., Ltd.) was deposited to a thickness of 200 nm, and a silicon-containing spin-on hard mask SHB-A940 (silicon content 43 wt %, Shin-Etsu Chemical Co., Ltd.) was deposited thereon to a thickness of 35 nm. On this substrate for trilayer process, each of the resist compositions (R-12 to R-15 in Table 5) or comparative resist compositions (R-29 to R-34 in Table 5) was spin coated and baked on a hot plate at 100° C. for 60 seconds, forming a resist film of 90 nm thick.

Using an ArF excimer laser immersion lithography scanner (NSR-610C by Nikon Corp., NA 1.30, a 0.98/0.74, dipole opening 90 degrees, s-polarized illumination), the resist film was exposed through a mask in a varying dose and baked (PEB) at an arbitrary temperature for 60 seconds. This was followed by development in butyl acetate for 30 seconds and rinsing with diisopentyl ether.

The mask used herein is a halftone phase shift mask (transmittance 6%) having a 45 nm line/90 nm pitch pattern (on-wafer size, actual on-mask size is 4 times the indicated size because of ¼ reduction projection exposure). A trench pattern corresponding to the light-shielded region was measured under CD-SEM (CG4000 by Hitachi High-Technologies Corp.). The optimum dose (Eop) is an exposure dose (mJ/cm²) which provides a trench width of 45 nm. A size variation (3σ) of the trench width at the optimum dose is determined at intervals of 10 nm over a range of 200 nm and reported as LER (nm).

As the exposure dose is reduced, the trench size is enlarged and the line size is reduced. The maximum of trench width below which lines can be resolved without collapse is determined and reported as collapse limit (nm). Higher values indicate greater collapse resistance and are preferable.

The results (optimum dose, LER and collapse limit) of the resist compositions are shown in Table 7.

TABLE 7

| | | Eop | LER | Collapse limit |
|---|---|---|---|---|
| | Resist | (mJ/cm²) | (nm) | (nm) |
| Evaluation Example 2-1 | R-12 | 21 | 4.0 | 50 |
| Evaluation Example 2-2 | R-13 | 27 | 3.4 | 56 |
| Evaluation Example 2-3 | R-14 | 25 | 3.6 | 52 |
| Evaluation Example 2-4 | R-15 | 23 | 3.6 | 54 |
| Evaluation Comparative | R-29 | 35 | 4.6 | 32 |
| Example 2-1 | | | | |
| Evaluation Comparative | R-30 | 41 | 3.9 | 40 |
| Example 2-2 | | | | |
| Evaluation Comparative | R-31 | 40 | 3.9 | 38 |
| Example 2-3 | | | | |
| Evaluation Comparative | R-32 | 39 | 4.1 | 39 |
| Example 2-4 | | | | |
| Evaluation Comparative | R-33 | 25 | 5.2 | 34 |
| Example 2-5 | | | | |
| Evaluation Comparative | R-34 | 51 | 3.8 | 38 |
| Example 2-6 | | | | |

It is evident from Table 7 that the resist compositions containing an ammonium salt and a polymer within the scope of the invention exhibit a low LER and improved collapse limit, when processed by the ArF exposure and organic solvent development.

While the invention has been illustrated and described in typical embodiments, it is not intended to be limited to the details shown. Any modified embodiments having substantially the same features and achieving substantially the same results as the technical idea disclosed herein are within the spirit and scope of the invention.

Japanese Patent Application No. 2015-098783 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A resist composition comprising
(A) a base resin comprising recurring units (A1) and (A2), and
(B) an ammonium salt having the general formula (3),
the recurring units (A1) having the general formula (1a) or (1b): 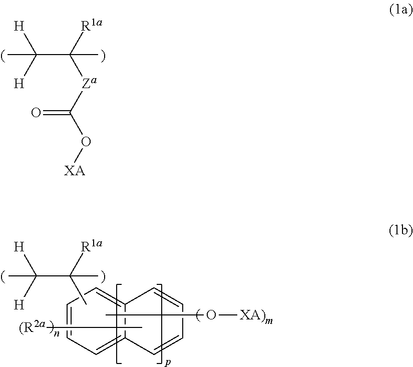
wherein R^{1a} is hydrogen, fluorine, methyl or trifluoromethyl, Z^{a} is a single bond or (backbone)-C(═O)—O—Z′—, Z′ is a straight C₁-C₁₀, branched or cyclic C₃-C₁₀ alkylene group which may contain a hydroxyl moiety, ether bond, ester bond or lactone ring, or phenylene or naphthylene group, XA is an acid labile group, R^{2a} is a straight C₁-C₁₀, branched or cyclic C₃-C₁₀ monovalent hydrocarbon group which may be substituted with or separated by a heteroatom, m is an integer of 1 to 3, n is an integer satisfying 0≦n≦5+2p−m, and p is 0 or 1,
the recurring units (A2) having the general formula (2a) or (2b): 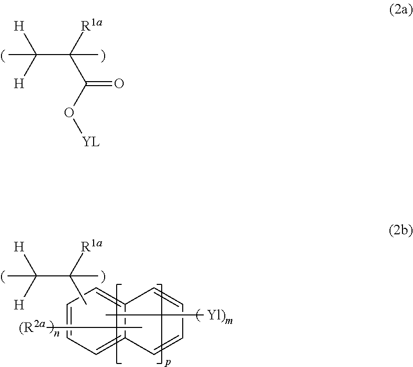
wherein R^{1a}, R^{2a}, m, n and p are as defined above, YL is hydrogen or a polar group having at least one structure selected from the group consisting of hydroxyl, cyano, carbonyl, carboxyl, ether bond, ester bond, sulfonic acid ester bond, carbonate bond, lactone ring, sultone ring, and carboxylic anhydride, 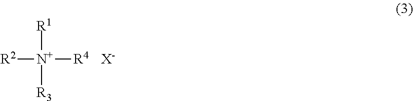
wherein R¹ to R⁴ are each independently a straight C₁-C₂₀, branched or cyclic C₃-C₂, monovalent hydrocarbon group which may be substituted with or separated by a heteroatom, any two or more of R³ to R⁴ may bond together to form a ring with the nitrogen atom to which they are attached, X⁻ is a structure of the general formula (3a), (3b) or (3c): 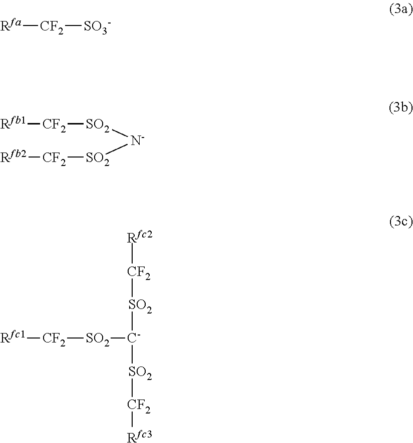
wherein R^{fa}, R^{fb1}, R^{fb2}, R^{fc1}, R^{fc2} and R^{fc3} are each independently fluorine or a straight C₁-C₄₀, branched or cyclic C₃-C₄₀ monovalent hydrocarbon group which may be substituted with or separated by a heteroatom, or a pair of R^{fb1} and R^{fb2}, or R^{fc1} and R^{fc2} may bond together to form a ring with the carbon atom to which they are attached and any intervening atoms.

2. The resist composition of claim 1 wherein the ammonium salt (B) has a structure represented by the general formula (4): 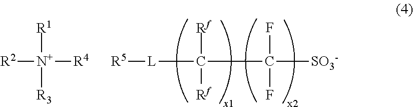
wherein R¹ to R⁴ are as defined above, R⁵ is a straight C₁-C₄₀, branched or cyclic C₃-C₄₀ monovalent hydrocarbon group which may be substituted with or separated by a heteroatom, R^{f1} is each independently hydrogen, fluorine or fluoroalkyl, L is a single bond or linking group, x1 is an integer of 0 to 10, and x2 is an integer of 1 to 5.

3. The resist composition of claim 1 wherein the ammonium salt (B) has a structure represented by the general formula (5): 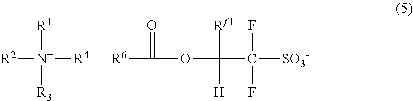
wherein R¹ to R⁴ are as defined above, R⁶ is a straight C₁-C₄₀, branched or cyclic C₃-C₄₀ monovalent hydrocarbon group which may be substituted with or separated by a heteroatom, and R^{f} is each independently hydrogen or trifluoromethyl.

4. The resist composition of claim 1 wherein the base resin (A) further comprises recurring units having the general formula (6a) or (6b): 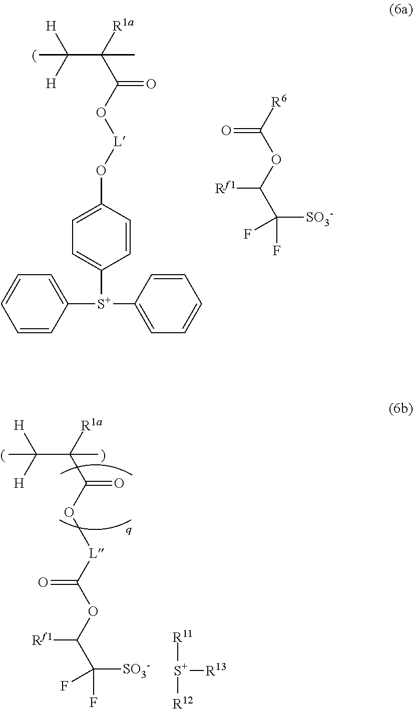
wherein R^{1a}, R⁶ and R^{f1} are as defined above, L′ is C₂-C₅ alkylene, R¹¹, R¹² and R¹³ are each independently a straight, branched or cyclic C₁-C₁₀ alkyl or alkenyl group which may be substituted with or separated by a heteroatom, or a C₆-C₁₈ aryl group which may be substituted with or separated by a heteroatom, or any two of R¹¹, R¹² and R¹³ may bond together to form a ring with the sulfur atom, L″ is a single bond or a straight C₁-C₂₀, branched or cyclic C₃-C₂₀ divalent hydrocarbon group which may be substituted with or separated by a heteroatom, q is 0 or 1, with the proviso that q is essentially 0 when L″ is a single bond.

5. The resist composition of claim 1, further comprising a photoacid generator having the general formula (7) or (8): 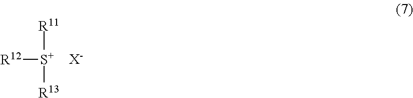
wherein R¹¹, R¹², R¹³, and X⁻ are as defined above, 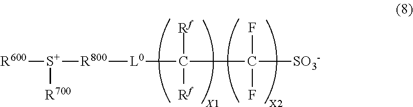
wherein x1, x2, and R^{f} are as defined above, L⁰ is a single bond or linking group, R⁶⁰⁰ and R⁷⁰⁰ are each independently a straight C₁-C₃₀, branched or cyclic C₃-C₃₀ monovalent hydrocarbon group which may be substituted with or separated by a heteroatom, R⁸⁰⁰ is a straight C₁-C₃₀, branched or cyclic C₃-C₃₀ divalent hydrocarbon group which may be substituted with or separated by a heteroatom, or any two or more of R⁶⁰⁰, R⁷⁰⁰, and R⁸⁰⁰ may bond together to form a ring with the sulfur atom.

6. The resist composition of claim 1, further comprising a nitrogen-containing compound.

7. The resist composition of claim 1, further comprising an onium salt having a structure represented by the general formula (9a) or (9b):
R^{q1}—SO₃⁻Mq⁺ (9a)
R^{q2}—CO₂⁻Mq⁺ (9b)
wherein R^{q1} is hydrogen or a straight C₁-C₄₀, branched or cyclic C₃-C₄₀ monovalent hydrocarbon group which may be substituted with or separated by a heteroatom, excluding that in formula (9a), a hydrogen atom on the α-position carbon atom relative to the sulfo group is substituted by fluorine or fluoroalkyl, R¹² is hydrogen or a straight C₁-C₄₀, branched or cyclic C₃-C₄₀ monovalent hydrocarbon group which may be substituted with or separated by a heteroatom, Mq⁺ is an onium cation having the general formula (c1), (c2) or (c3): 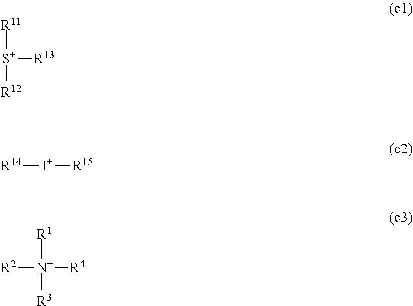
wherein R¹, R², R³, R⁴, R¹¹, R¹², and R¹³ are as defined above, R¹⁴ and R¹⁵ are each independently a straight, branched or cyclic C₁-C₁₀ alkyl or alkenyl group which may be substituted with or separated by a heteroatom, or a C₆-C₁₈ aryl group which may be substituted with or separated by a heteroatom.

8. The resist composition of claim 1, further comprising a surfactant which is insoluble or substantially insoluble in water, but soluble in an alkaline developer and/or a surfactant which is insoluble or substantially insoluble in water and an alkaline developer.

9. A process for forming a pattern, comprising the steps of coating the resist composition of claim 1 onto a substrate, prebaking the coating to form a resist film, exposing the resist film through a photomask to KrF excimer laser, ArF excimer laser, EB or EUV, baking, and developing the resist film in a developer.

10. The process of claim 9 wherein the exposure step is performed by immersion lithography while keeping a liquid having a refractive index of at least 1.0 between the resist film and a projection lens.

11. The process of claim 10, further comprising the step of coating a protective film on the resist film, wherein the liquid is kept between the protective film and the projection lens.
